(19) United States
(12) Patent Application Publication
(10) Pub. No.: US 2010/0187987 A1
(43) Pub. Date: Jul. 29, 2010

(54) ELECTRODE-ATTACHED SUBSTRATE, METHOD FOR PRODUCING THE SAME, ORGANIC LED ELEMENT AND METHOD FOR PRODUCING THE SAME

(75) Inventor: Nobuhiro NAKAMURA, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Asahi Glass Company, Limited, Chiyoda-ku (JP)

(21) Appl. No.: 12/693,745

(22) Filed: Jan. 26, 2010

(30) Foreign Application Priority Data
Jan. 26, 2009 (JP) 2009-014795

(51) Int. Cl. H01J 1/62; H05K 1/09; B05D 5/06

(52) U.S. Cl. 313/504; 174/256; 427/66

(57) ABSTRACT

The present invention relates to: an electrode-attached substrate including a reflective substrate, a scattering layer formed on the substrate and composed of a glass layer including a plurality of scattering materials, and a translucent electrode formed on the scattering layer; a method for producing the same; an organic LED element using the electrode-attached substrate; and a method for producing the same.

### FIELD OF THE INVENTION

The present invention relates to an electrode-attached substrate, a method for producing the same, an organic LED element and a method for producing the same. In particular, the present invention relates to a light-extraction structure of an organic LED (organic light emitting diode) or the like.

### BACKGROUND OF THE INVENTION

An organic LED element is one in which an organic layer is put between electrodes, and a voltage is applied between the electrodes to inject holes and electrons, which are allowed to be recombined in the organic layer, thereby extracting light that a light-emitting molecule emits in the course of transition from an excited state to a ground state, and has been used for display, backlight and lighting applications.

The refractive index of the organic layer is from about 1.8 to about 2.1 at 430 nm. On the other hand, the refractive index, for example, at the time when ITO (indium tin oxide) is used as a translucent electrode layer is generally from about 1.9 to about 2.1, although it varies depending on the ITO film-forming conditions or composition (Sn—In ratio). Like this, the organic layer and the translucent electrode layer are close to each other in refractive index, so that emitted light reaches an interface between the translucent electrode layer and a translucent substrate without totally reflecting between the organic layer and the translucent electrode layer. A glass or resin substrate is usually used as the translucent substrate, and the refractive index thereof is from about 1.5 to about 1.6, which is lower in the refractive index than the organic layer or the translucent electrode layer. Considering Snell's law, light which tries to enter the glass substrate at a shallow angle is reflected by total reflection in an organic layer direction, and reflected again at a reflective electrode to reach the interface of the glass substrate again. At this time, the incident angle to the glass substrate does not vary, so that reflection is repeated in the organic layer and the translucent electrode layer to fail to extract the light from the glass substrate to the outside. According to an approximate estimate, it is known that about 60% of the emitted light cannot be extracted by this mode (organic layer-translucent electrode layer propagation mode). The same also occurs at an interface between the substrate and the air, whereby about 20% of the emitted light propagates in the glass and fails to be extracted (substrate propagation mode). Accordingly, the amount of the light which can be extracted to the outside of the organic LED element is less than 20% of the emitted light in the present circumstances.

JP-A-2004-296437 describes an element construction where a low refractive index layer containing no particle and a light-scattering particle-containing seeped light-scattering layer are formed between a translucent electrode and a substrate so as to enhance the light extraction efficiency (JP-A-2004-296437, paragraph 0113). The element of this construction is fabricated to more efficiently extract light by providing a light-scattering particle-containing seeped light-scattering layer on the light extraction side of a substrate and utilizing seepage of light.

The organic LED element above is a so-called bottom emission-type element of extracting light from the substrate side. Since an inexpensive highly-protective glass substrate can be used and optimal layer arrangement is constructed so as to extract light from the substrate side is conducted, the film thickness thereof is free from unevenness due to difference in height of the underlying layer.

Meanwhile, as described in JP-A-2004-22438, a so-called top emission-type organic LED element of extracting light from the element-formed surface side of a substrate has also been proposed, and there is described an element construction where a flattening film having a refractive index higher than the refractive index of a light-emitting layer is formed between a scattering layer or reflective scattering layer and an element part so as to reduce deterioration of the element due to unevenness (see, JP-A-2004-22438, paragraph 0054).

### SUMMARY OF THE INVENTION

In recent years, with an increasing tendency to demand an organic LED element having high brightness characteristics, the electric current flowed becomes large and this incurs a problem of heat dissipation. Use of a substrate having poor heat dissipation, such as glass, involves a rise in temperature of the element, causing a problem such as acceleration of brightness deterioration or short circuiting between electrodes, and accordingly, an element using a substrate with good thermal conductivity is required. As the substrate having good thermal conductivity, a reflective substrate made of a metal, a ceramic or the like may be mentioned, and practical application of an optical device such as organic LED element using a reflective substrate is eagerly anticipated.

In the case of flowing a large current to obtain high brightness characteristics, when a reflective substrate is used, the latitude in laying out a wiring pattern is broadened and the extraction resistance can be reduced, however, on the other hand, reflected light by the reflective substrate escapes from the side surface of the substrate or element, resulting in insufficient extraction efficiency.

The present invention has been made under these circumstances, and an object of the present invention is to provide a high-efficiency long-life optical device such as organic LED element while enhancing the light extraction efficiency.

The electrode-attached substrate of the present invention comprises a reflective substrate, a scattering layer formed on the substrate and composed of a glass layer comprising a plurality of scattering materials, and a translucent electrode formed on the scattering layer.

According to this construction, the presence of a scattering layer enables efficiently extracting light by top emission and the light extraction efficiency is enhanced.

The present invention includes the electrode-attached substrate as described above, wherein the scattering layer is composed of a glass comprising a base material having a first refractive index for at least one wavelength of light to be transmitted and a plurality of scattering materials being dispersed in the base material and having a second refractive index different from the refractive index of the base material, and wherein a distribution of the scattering materials in the scattering layer decreases from an inside of the scattering layer toward the translucent electrode.

The present invention includes the electrode-attached substrate as described above, wherein the translucent electrode has a third refractive index equal to or lower than the first refractive index.

The translucent electrode may be formed such that the third refractive index is higher than the first refractive index and the difference therebetween is 0.2 or less.

The present invention includes the electrode-attached substrate as described above, wherein a density ρ₃ of the scattering materials at a distance x (x≦0.2 μm) from a surface of the scattering layer on a translucent electrode side and a density ρ₄ of the scattering materials at a distance x of 2 μm satisfy ρ₄>ρ₃.

The present invention includes the electrode-attached substrate as described above, wherein a surface roughness Ra of a surface of the scattering layer is 30 nm or less.

The present invention includes the electrode-attached substrate as described above, wherein the content of the scattering materials in the scattering layer is at least 1 vol %.

The present invention includes the electrode-attached substrate as described above, wherein the scattering materials are pores.

The present invention includes the electrode-attached substrate as described above, wherein the scattering materials are material particles having a composition different from that of the base material.

The present invention includes the electrode-attached substrate as described above, wherein the scattering materials are precipitated crystals of the glass constituting the base material.

The present invention includes the electrode-attached substrate as described above, wherein the number of the scattering materials per 1 mm² of the scattering layer is at least 1×10⁴.

The present invention includes the electrode-attached substrate as described above, wherein, in the scattering materials, the ratio of scattering materials having a maximum length of 5 μm or more is 15 vol % or less.

The present invention includes the electrode-attached substrate as described above, wherein the scattering layer is selectively formed to constitute a desired pattern on the reflective substrate.

The present invention includes the electrode-attached substrate as described above, wherein the first refractive index for at least one wavelength of wavelengths λ (430 nm<λ<650 nm) is 1.8 or more.

The present invention includes the electrode-attached substrate as described above, wherein the scattering layer has an average thermal expansion coefficient over the range of 100 to 400° C. of 70×10⁻⁷ to 95×10⁻⁷ (° C.⁻¹), and a glass transition temperature of 450 to 550° C.

The present invention includes the electrode-attached substrate as described above, wherein the base material of the scattering layer is a glass containing, in terms of mol %, from 15 to 30% of P₂O₅, from 0 to 15% of SiO₂, from 0 to 18% of B₂O₃, from 5 to 40% of Nb₂O₅, from 0 to 15% of TiO₂, from 0 to 50% of WO₃, from 0 to 30% of Bi₂O₃, provided that Nb₂O₅+TiO₂+WO₃+Bi₂O₃ is from 20 to 60%, from 0 to 20% of Li₂O, from 0 to 20% of Na₂O, from 0 to 20% of K₂O, provided that Li₂O+Na₂O+K₂O is from 5 to 40%, from 0 to 10% of MgO, from 0 to 10% of CaO, from 0 to 10% of SrO, from 0 to 20% of BaO, from 0 to 20% of ZnO and from 0 to 10% of Ta₂O₅.

The present invention includes the electrode-attached substrate as described above, wherein the scattering layer contains from 20 to 30 mol % of P₂O₅, from 3 to 14 mol % of B₂O₃, from 10 to 20 mol % in total of Li₂O, Na₂O and K₂O, from 10 to 20 mol % of Bi₂O₃, from 3 to 15 mol % of TiO₂, from 10 to 20 mol % of Nb₂O₅ and from 5 to 15 mol % of WO₃.

The present invention includes the electrode-attached substrate as described above, wherein the reflective substrate is a metal-made substrate.

Thanks to this construction, heat dissipation is enhanced and use under flow of a large electric current is facilitated.

The present invention includes the electrode-attached substrate as described above, wherein the reflective substrate is a substrate whose surface is coated with a metal film.

The method for producing an electrode-attached substrate of the present invention comprises steps of: preparing a reflective substrate; forming on the substrate a scattering layer composed of a glass layer comprising a plurality of scattering materials; and forming a translucent electrode on the scattering layer.

The present invention includes the method for producing an electrode-attached substrate as described above, wherein the step of forming a scattering layer includes steps of coating a glass powder-containing coating material on the substrate and firing the coated glass powder, the scattering layer formed comprises a base material having a first refractive index and a plurality of scattering materials being dispersed in the base material and having a second refractive index different from the refractive index of the base material, and the intralayer distribution of scattering materials in the scattering layer decreases from an inside of the scattering layer toward an outermost surface thereof.

The present invention includes the method for producing an electrode-attached substrate as described above, wherein the firing step includes a step of firing the glass powder at a temperature which is 40 to 100° C. or more higher than a glass transition temperature of the coated glass material.

The present invention includes the method for producing an electrode-attached substrate as described above, wherein the firing step includes a step of firing the glass powder at a temperature which is 60 to 100° C. or more higher than the glass transition temperature of the coated glass material.

The present invention includes the method for producing an electrode-attached substrate as described above, wherein the firing step includes a step of firing the glass powder at a temperature which is 40 to 60° C. higher than the glass transition temperature of the coated glass material.

The present invention includes the method for producing an electrode-attached substrate as described above, wherein the coating step includes a step of coating a glass powder having a particle diameter D₁₀ of 0.2 μm or more and a particle diameter D₉₀ of 5 μm or less.

The method for producing an organic LED element of the present invention comprises the method for producing an electrode-attached substrate as described above, a step of forming a layer having a light-emitting function on the translucent electrode as a first electrode, and a step of forming a second electrode on the layer having a light-emitting function.

The organic LED element of the present invention comprises a reflective substrate, a scattering layer formed on the substrate and composed of a glass comprising a plurality of scattering materials, a first translucent electrode formed on the scattering layer, an organic layer formed on the first translucent electrode, and a second translucent electrode formed on the organic layer.

The present invention includes the organic LED element as described above, wherein the reflective substrate is a metal-made substrate.

The present invention includes the organic LED element as described above, wherein the reflective substrate is a substrate whose surface is coated with a metal film.

Here, in the case where a translucent substrate (e.g., glass substrate) coated with a metal film is used as the reflective substrate, both formation of a scattering layer on the translucent substrate side and formation of a scattering layer on the metal film side are effective.

The present invention includes the organic LED element as described above, wherein the scattering layer comprises a base material having a first refractive index for at least one wavelength of wavelengths of emitted light of the organic LED element and a plurality of scattering materials being positioned inside of the base material and having a second refractive index different from the refractive index of the base material and a distribution of the scattering materials in the scattering layer decreases from a inside of the scattering layer toward the translucent electrode.

The present invention includes the organic LED element as described above, wherein the first translucent electrode is formed on the scattering layer and has, at the above-described wavelength, a third refractive index equal to or lower than the first refractive index.

In the organic LED element above, the first translucent electrode may be formed on the scattering layer such that the third refractive index is higher than the first refractive index and the difference therebetween is 0.2 or less.

The method for producing an organic LED element of the present invention comprises steps of: preparing a reflective substrate; forming on the substrate a scattering layer composed of a glass comprising a base material having a first refractive index for at least one wavelength of wavelengths of emitted light of the organic LED element and a plurality of scattering materials being positioned inside of the base material and having a second refractive index different from the refractive index of the base material; forming a first translucent electrode on the scattering layer; forming an organic layer on the first translucent electrode; and forming a second translucent electrode on the organic layer.

According to the present invention, an organic LED element having a long lifetime and high reliability and capable of dissipating heat from the substrate side can be provided. An electrode-attached substrate capable of enhancing the light extraction efficiency and providing an optical device with high extraction efficiency can be provided.

Also, the scattering layer is composed of a glass, so that stability and high strength can be realized and without increasing the thickness as compared with the original translucent substrate composed of a glass, a translucent substrate excellent in the scattering property can be provided.

According to the present invention, an organic LED element succeeded in enhancing the extraction efficiency up to 98% of emitted light can be provided.

### BRIEF DESCRIPTION OF THE DRAWINGS

FIGS. 1(a) and 1(b) are cross-sectional views showing structures of the electrode-attached substrate and the organic LED element according to embodiment 1 of the present invention.

FIG. 2 is a view showing the relationship between the amount (W) of the extracted light and the density (particles/mm³) of the scattering material and the relationship between the content (vol %) of the scattering material and the density (particles/mm³) of the scattering material.

FIG. 3 is a view showing the relationship between the amount (W) of the extracted light and the diameter (μm) of the scattering material and the relationship between the content (vol %) of the scattering material and the diameter (μm) of the scattering material.

FIG. 4 is a view showing the relationship between the amount (W) of the extracted light and the refractive index of the scattering material.

FIG. 5 is a view showing the relationship between the amount (W) of the extracted light and the refractive index of the base material of the scattering layer.

FIG. 6 is a view showing the relationship between the amount (W) of the extracted light and the transmittance (%/mm) of the base material of the scattering layer.

FIG. 7 is a view showing the relationship between the amount (W) of the extracted light and the reflectivity (%) of the substrate.

FIG. 8 is a view showing the relationship between the amount (W) of the extracted light and the film thickness (μm) of the scattering layer.

FIG. 9 is a view showing the relationship between the amount (W) of the extracted light and the number (particles/mm²) of scattering particles per unit area.

FIG. 10 is a cross-sectional view of an organic LED element that performs a simulation.

FIG. 11 is a view showing the relationship between the loss (%) due to waveguide mode and the refractive index of the translucent electrode.

FIG. 12 is a schematic view showing a state at the coating of glass particles constituting the scattering layer of the electrode-attached substrate according to embodiment 1 of the present invention.

FIG. 13 is a schematic view showing a state at the firing of glass particles constituting the scattering layer of the electrode-attached substrate according to embodiment 1 of the present invention.

FIG. 14 is a schematic view showing a state of the scattering layer when fired at a temperature lower than the softening point of the glass as Comparative Example of the present invention.

FIG. 15 is a schematic view showing a state of the scattering layer (when fired at a temperature sufficiently higher than the softening point of the glass) according to embodiment 1 of the present invention.

FIG. 16 is a schematic view showing a state of surface waviness of the scattering layer according to embodiment 1 of the invention.

FIG. 17 is a schematic view showing a microscopic concave potion of the scattering layer surface.

FIG. 18 is a schematic view showing a microscopic concave portion of the scattering layer surface.

FIG. 19 is a schematic view showing a surface state of the scattering layer according to embodiment 1 of the present invention.

FIG. 20 is a schematic view showing a surface state of the scattering layer in Comparative Example (when the firing temperature is too high).

FIG. 21 is a view showing the organic LED element according to embodiment 2 of the present invention.

FIG. 22 is a view showing the organic LED element according to embodiment 3 of the present invention.

FIG. 23 is a flow chart showing the production method of a substrate for an organic LED element according to the present invention.

FIG. 24 is a flow chart showing the production method of an organic LED element according to the present invention.

FIG. 25 is a cross-sectional view schematically showing a construction of an organic LED display device.

FIG. 26 is a cross-sectional view showing the organic LED element according to embodiment 4 of the present invention.

FIG. 27 is the results when observed from the front under conditions of Case 1 and Case 2.

FIG. 28 is a cross-sectional view taken along line A-A as seen from the direction C in FIG. 29, showing the structure of the evaluation element.

FIG. 29 is a top view of the evaluation element seen from the direction B in FIG. 28.

FIG. 30 is a view showing the measurement results of the relationship between the firing temperature and the surface roughness Ra of the scattering layer of the electrode-attached substrate in Example 2 of the present invention.

### DESCRIPTION OF REFERENCE NUMERALS AND SIGNS

100 Electrode-attached substrate
101 Reflective substrate
102 Scattering layer
103 Translucent electrode
104 Scattering material
105 Base material
110 Organic layer
120 Translucent electrode
110LER Light-emitting region
Rc Light-receiving part

### DETAILED DESCRIPTION OF THE INVENTION

### Embodiment 1

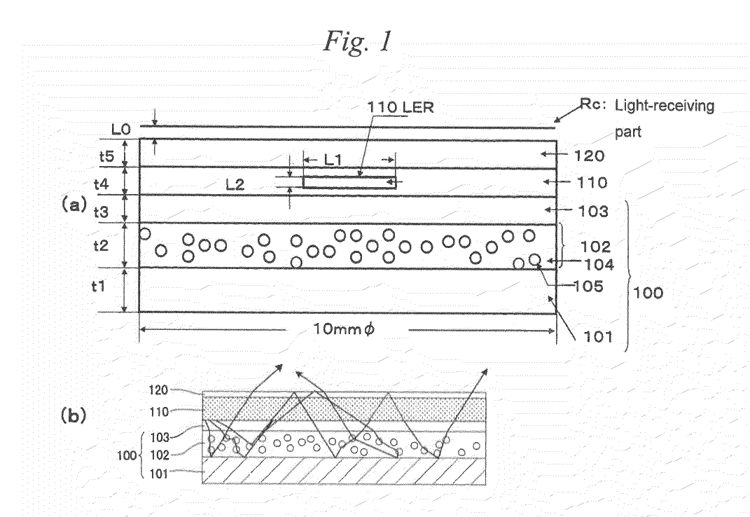

The electrode-attached substrate and the organic LED element according to embodiment 1 of the present invention are described below by referring to the drawings. FIG. 1 is a cross-sectional view showing a structure of an organic LED element equipped with the electrode-attached substrate, where (a) is a cross-sectional explanatory view and (b) is a schematic cross-sectional view showing the light exit direction.

The organic LED element of the present invention comprises, as shown in FIG. 1, an electrode-attached substrate 100, an organic layer 110 and a translucent electrode 120. The electrode-attached substrate 100 is composed of a reflective substrate 101, a scattering layer 102 and a translucent electrode 103.

The thickness t1 of the reflective substrate 101 is 1 mm, and the scattering layer 102 formed thereon has a film thickness t2 of 30 μm and contains a 1 μm-diameter scattering material 104 having a refractive index of 1.0 in a base material 105 having a refractive index of 2.0 at a density of 10⁷ particles/mm³. The translucent electrode 103 is composed of an indium tin oxide layer having a film thickness t3 of 1.5 μm and a refractive index of 1.9, on which the organic layer 110 having a film thickness t4 of 1.6 μm and a refractive index of 1.9 as a layer having a light-emitting function and the translucent electrode 120 composed of an indium tin oxide layer having a film thickness t5 of 0.8 μm and a refractive index of 1.9 are formed to constitute an element part. Here, as for the reflective substrate 101, a metal material ensuring a reflectivity of 100% is selected.

The electrode-attached substrate 100 for use in the present invention comprises, as described above, a reflective substrate 101, a scattering layer 102 formed on the substrate 101 and composed of a glass, and a translucent electrode 103, wherein the scattering layer comprises a base material 105 having a first refractive index for one wavelength of light to be transmitted and a plurality of scattering materials 104 being dispersed in the base material and having a second refractive index different from the refractive index of the base material, and the distribution of the scattering materials in the scattering layer decreases from the inside of the scattering layer toward the translucent electrode. This translucent electrode 103 has a third refractive index equal to or lower than the first refractive index.

Also, the density ρ₁ of the scattering material at a half thickness (δ/2) of the scattering layer 102 composed of a glass and the density ρ₂ of the scattering material at a distance x (δ/2<x≦δ) from the scattering layer surface on the side facing the translucent electrode (namely, the surface on the substrate side) satisfy ρ₁≧ρ₂.

Furthermore, the density ρ₃ of the scattering material at a distance x (x≦0.2 μm) from the surface of the scattering layer containing the glass on the translucent electrode side and the density ρ₄ of the scattering material at a distance x of 2 μm preferably satisfy ρ₄>ρ₃.

In addition, the density ρ₃ of the scattering material at a distance x (x≦0.2 μm) from the surface of the scattering layer containing the glass on the translucent electrode side and the density ρ₅ of the scattering material at a distance x of 5 μm preferably satisfy ρ₅>ρ₃.

According to these constructions, the probability that a scattering material composed of a pore, a precipitated crystal or a material differing in the composition from the base material is present in the surface layer of or beneath the scattering layer composed of a glass layer is lower than in the inside of the scattering layer, so that a smooth surface can be obtained. Therefore, for example, in the case of forming an organic LED element, the surface of the translucent substrate, that is, the surface of the scattering layer, is smooth and in turn, the surface of the translucent electrode (first electrode) formed thereon is smooth, so that when, for example, a layer having a light-emitting function is formed thereon by a coating method or the like, the layer having a light-emitting function can be uniformly formed and the inter-electrode distance between the translucent electrode and the surface of a translucent electrode (second electrode) formed on the layer having a light-emitting function can be made uniform. As a result, it does not occur that a large current is locally applied to the layer having a light-emitting function, and the lifetime can be prolonged. Furthermore, in the case of fabricating a display device constituted by fine pixels, such as high-resolution display, although a fine pixel pattern needs to be formed and unevenness of the surface not only gives rise to occurrence of variation in the position or size of pixels but also causes a problem that an organic LED element is short-circuited by the unevenness, a fine pattern can be formed with high precision.

Also, by virtue of taking a top emission structure using a reflective substrate, the element can be formed with no restriction in the laying of wiring on the substrate or in the film thickness and can be reduced in the resistance, and this enables fabrication of a large-current device.

In addition, when a substrate with good thermal conductivity, such as metal substrate or metal oxide substrate, is used as the reflective substrate, heat can be successfully dissipated and an organic LED element having good characteristics and high reliability can be provided.

Calculation Method

In order to learn the characteristics of the scattering layer, the present inventors examined effects of respective parameters on the extraction efficiency by performing optical simulations. The computational software used is LightTools manufactured by CYBERNET Systems Co., Ltd. This software is a ray trace software and at the same time, allows applying a theoretical formula of Mie scattering to the scattering layer. The model shown in FIG. 1 is used for the calculation. Here, as shown in FIG. 1, an organic electroluminescence element having a diameter of 10 mmφ, which is a laminate containing a light-emitting part 110LER having a thickness L2 of 1.2 μm and a square shape with sides L1 each 2 mm long, is envisaged. A light-receiving part Rc in the form of a 10 mm-diameter circle is provided at 0.1 μm above the element. The thickness of the organic layer 110 used as a layer having a light-emitting function, such as charge-injection-transport layer or light-emitting part, is actually from about 0.1 μm to about 0.3 μm in total, but in the ray trace, the angle of ray does not change even when the thickness is changed and therefore, the above-described value is used as the computable film thickness. As for the refractive index of each layer, the above-described value is also used. The scattering layer 102 is composed of a base material and a scattering particle, and for the scattering particle, 1 μm-diameter spheres having a refractive index of 1.0 are distributed at a density of 10⁷ (particles/mm³). The reflectivity of the reflective substrate 101 is set to 100%, and each layer is set to have no absorption. In the light-emitting part 110LER inside of the organic layer 110, light at a wavelength of 550 nm is assumed to exit from 6 faces in total without having directivity. The calculation is made by taking the total light flux amount as 1 W and the number of light rays as 10,000. The light extraction efficiency is calculated as “light (W) arrived at light-receiving part Rc/1 (W)×100(%)”. Strictly considered, a waveguide mode caused by interference is established, because the organic layer is thin, but the results are not largely changed even when the light is geometrically-optically treated, and therefore, this calculation is sufficient for estimating the effects by the construction of the present invention. However, in the case where the refractive index of the translucent electrode 103 becomes larger than the refractive index of the base material of the scattering layer, the waveguide needs to be taken into consideration and therefore, a waveguide calculation is separately performed. Based on these conditions, the change in the amount of the extracted light when changing each parameter is calculated.

In Case of Having No Scattering Layer

The amount of the extracted light in a structure having no scattering layer was 0.150 W. From this, the extraction efficiency is found to be 15.0%.

Density of Scattering Material in Scattering Layer

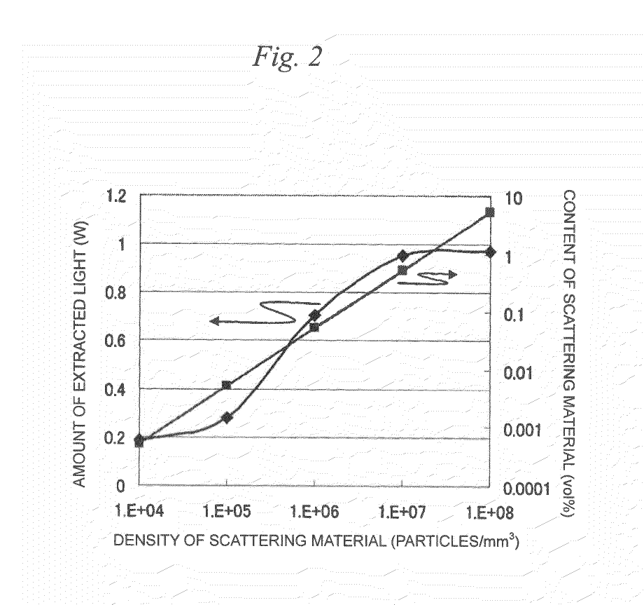

FIG. 2 is a view showing the relationship between the amount of the extracted light and the density of the scattering material. As shown in FIG. 2, as the density of the scattering material in the scattering layer increases, the amount of the extracted light is increased. The extraction efficiency is 18.5% even when the number of scattering particles is 10⁴ particles/mm³, and improvement of the amount of light extracted is admitted as compared with the above-described case of having no scattering layer, but when the number of scattering particles is 10⁵ particles/mm³, the extraction efficiency becomes 25% or more. The number of scattering particles is more preferably 10⁶ particles/mm³ or more, and in this case, the extraction efficiency becomes 70% or more and is more enhanced. Also, when the number of scattering particles is 10⁷ particles/mm³ or more, the extraction efficiency becomes 90% or more and this is most preferred.

Size of Scattering Material

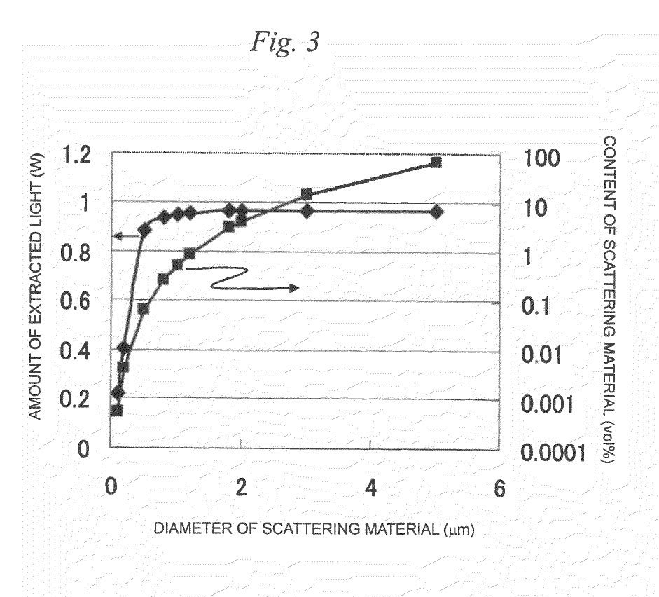

FIG. 3 shows the measurement results of the relationship between the diameter of the scattering particle and the amount of the extracted light. As the scattering particle diameter becomes larger, the amount of the extracted light is increased. Increase in the size of the scattering particle makes it difficult to uniformly dispose the scattering particles inside of the glass and therefore, the scattering particle diameter is preferably from 0.1 to 5 μm, more preferably from 0.2 to 3 μm, and most preferably from 0.5 to 2 μm. Also, from FIGS. 2 and 3, an improvement effect is admitted even when the content of the scattering particle is 0.001 vol %, but the content of the scattering particle is preferably 0.1 vol % or more, more preferably 1 vol % or more, and most preferably 5 vol % or more.

Refractive Index of Scattering Material

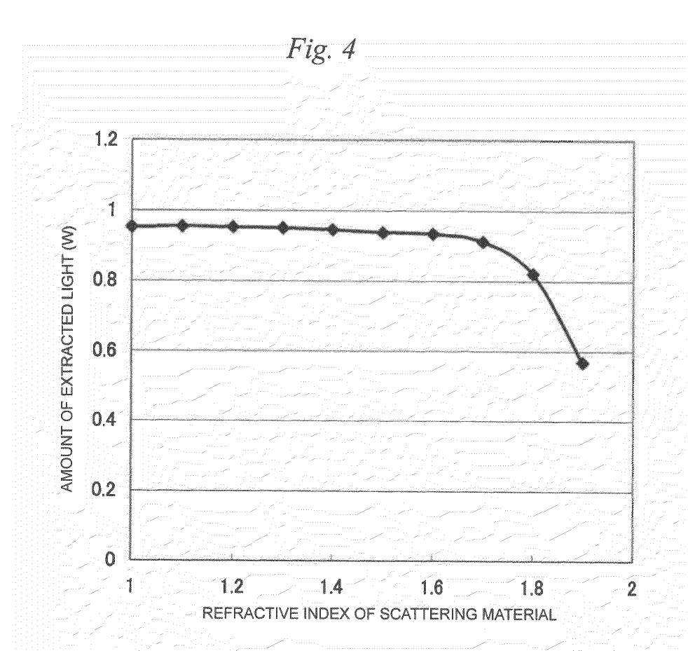

FIG. 4 shows the measurement results of the relationship between the refractive index of the scattering material and the amount of the extracted light. Here, the refractive index of the base material of the scattering layer is 2.0. The light extraction is improved when the refractive index difference between the base material and the scattering material of the scattering layer is 0.1 or more, but the refractive index difference is preferably 0.2 or more, more preferably 0.3 or more.

Refractive Index of Base Material of Scattering Layer

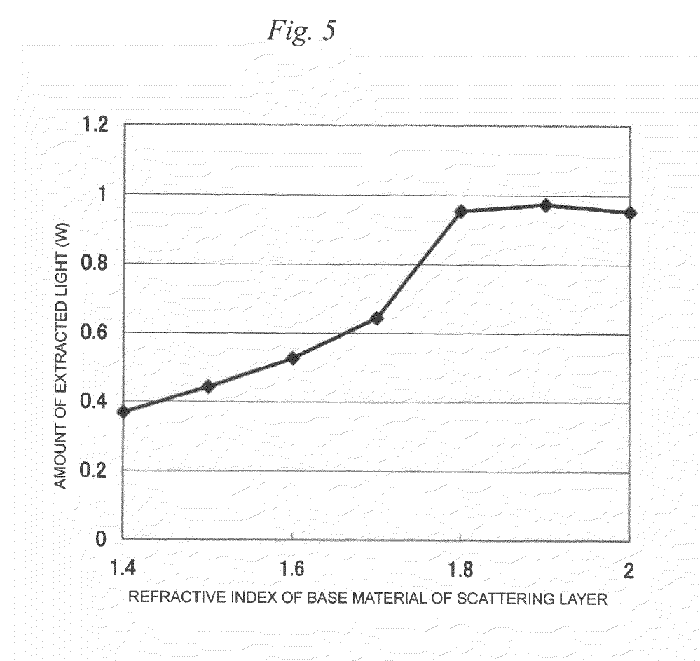

FIG. 5 shows the measurement results of the relationship between the refractive index of the base material of the scattering layer and the amount of the extracted light. In the case where the refractive index of the base material is equal to or larger than the refractive index of the translucent electrode, the amount of the extracted light is high and this is preferred. As the refractive index of the base material becomes smaller, the amount of the extracted light is decreased. Incidentally, when the refractive index of the base material is smaller than the refractive index of the translucent electrode, the waveguide needs to be taken into consideration and this is described later.

Transmittance of Base Material of Scattering Layer

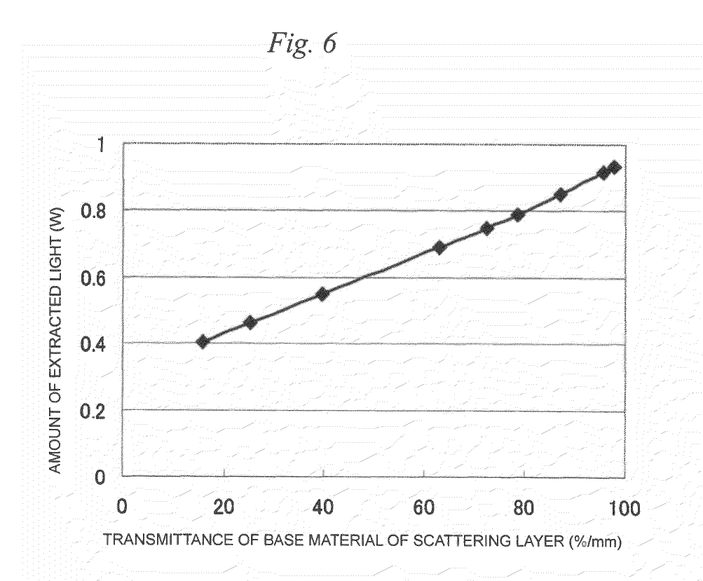

FIG. 6 shows the measurement results of the relationship between the transmittance as a bulk of the base material of the scattering layer and the amount of the extracted light. An extraction efficiency of 40% or more can be obtained when the transmittance with a thickness of 1 mm is 20% or more. Also, an extraction efficiency of 70% or more can be obtained when the transmittance with a thickness of 1 mm is 70% or more. More preferably, the transmittance with a thickness of 1 mm is 95% or more. This is most preferred because an extraction efficiency of 90% or more can be obtained.

Reflectivity of Substrate

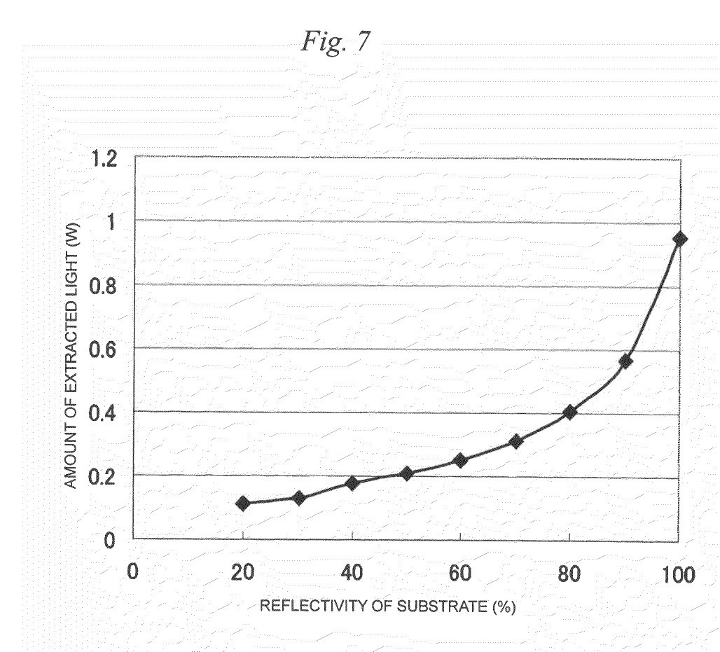

FIG. 7 shows the measurement results of the relationship between the reflectivity of the substrate and the amount of the extracted light. Here, mirror reflection is envisaged, but a diffusive-reflective substrate may also be used. It is apparent from this Figure that as the reflectivity decreases, the amount of the extracted light is decreased. The extraction efficiency becomes 20% or more when the reflectivity is 50% or more. The reflectivity is preferably 80% or more and in this case, the extraction efficiency becomes 40% or more. More preferably, the reflectivity is 90% or more, and this is most preferred because an extraction efficiency of 55% or more can be obtained.

Thickness of Scattering Layer

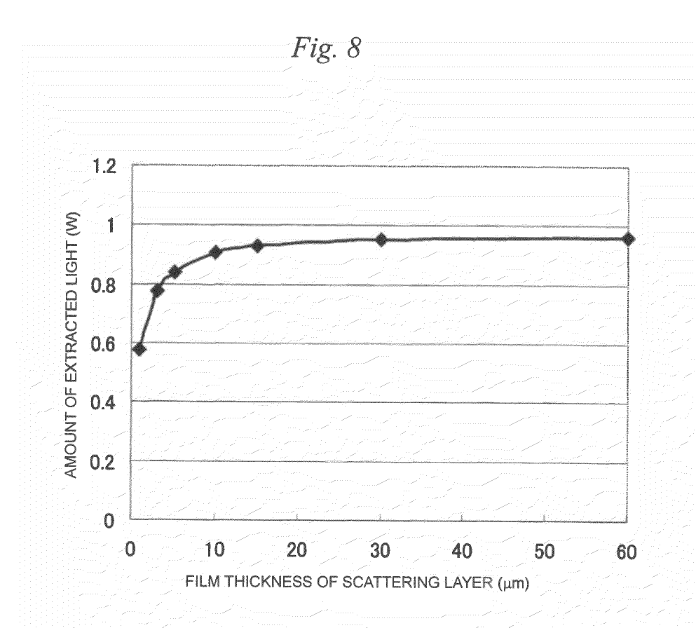

FIG. 8 shows the amounts of the extracted light when the thickness of the scattering layer is changed. Here, the density of the scattering particle is 10⁷ (particles/mm³), and the particle diameter is 1 μm. In this way, as the film thickness of the scattering layer becomes larger, the extraction efficiency is enhanced. An extraction efficiency of 55% or more can be obtained when the film thickness of the scattering layer is 1 μM or more, but the film thickness is preferably 5 μm or more and in this case, light extraction of 80% or more is possible. More preferably, the film thickness is 10 μm or more, and this is most preferred because light extraction of 90% or more can be obtained.

Number Density of Scattering Particle per Unit Area of Scattering Layer

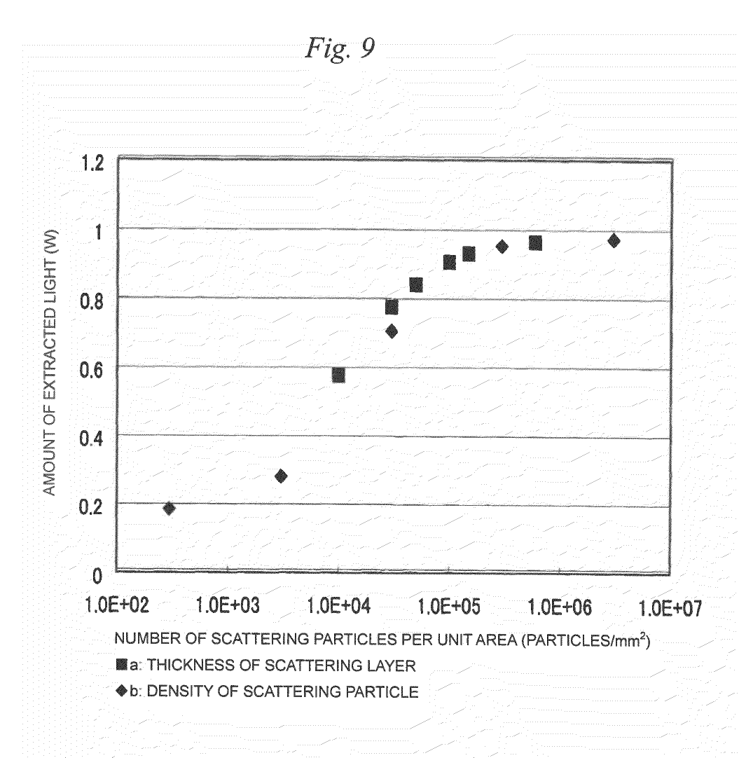

The change in the amount of the extracted light when changing the density of the scattering particle and the thickness of the scattering layer is converted into the relationship between the number of scattering particles per unit area of the scattering layer and the amount of the extracted light. The results are shown in FIG. 9, where “a” indicates the thickness t2 of the scattering layer.

As seen from the results, the number of scattering particles is preferably 10⁴ (particles/mm²) or more, where the light extraction efficiency is 50% or more, more preferably 10⁵ (particles/mm²) or more, where the light extraction efficiency is 80% or more, and most preferably 10⁶ (particles/mm²) or more, where the light extraction efficiency is 90% or more. The number of scattering particles per unit area also changes when the thickness t2 of the scattering layer is changed without changing the density of the scattering particle.

Waveguide Consideration of Relationship Between Refractive Index of Base Material of Scattering Layer and Refractive Index of Translucent Electrode

As described above, when the refractive index of the translucent electrode 103 is larger than the refractive index of the base material of the scattering layer, the waveguide must be taken into consideration.

The simulation results of the relationship between the refractive index of the base material of the scattering layer and the refractive index of the translucent electrode by taking the waveguide into consideration are described below with reference to the drawings. The term “waveguide consideration” as used herein means to calculate the abundance ratio of a mode that is allowed to be present in the translucent electrode. More specifically, light is allowed to enter the organic layer from outside, and to what extent the light is transferred into the translucent electrode from the organic layer and propagated through the translucent electrode with no leakage, is calculated.

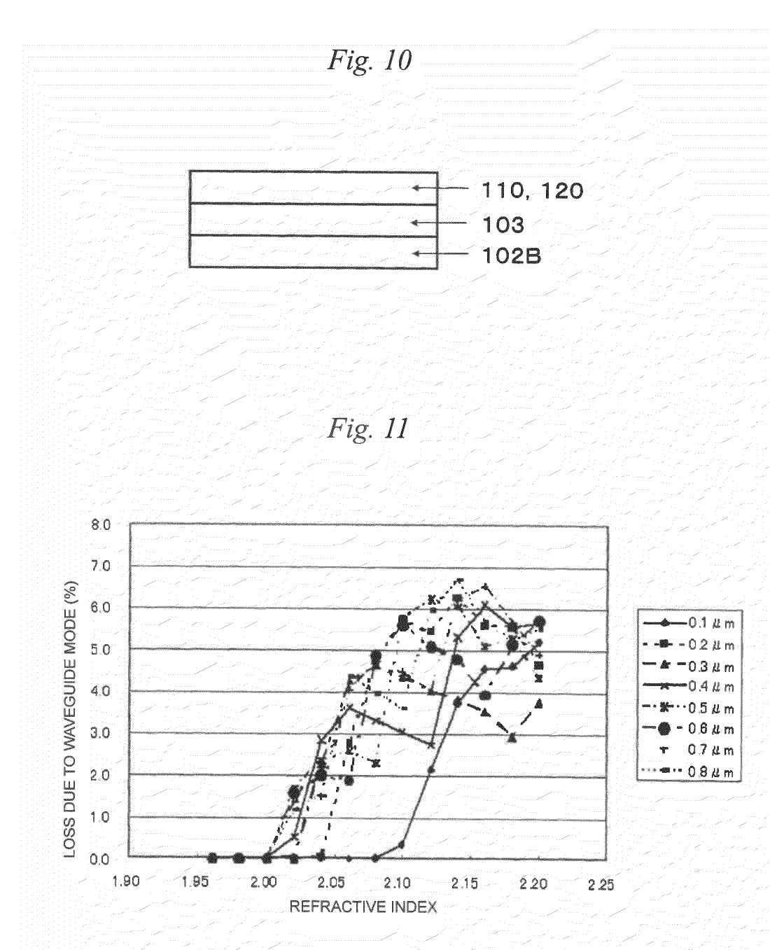

FIG. 10 is a cross-sectional view of an organic LED element sample that is envisaged for the simulation. The organic LED element of this sample comprises a scattering layer 102 having a high refractive index, a translucent electrode 103 provided on the scattering layer 102, an organic layer 110 provided on the translucent electrode 103, and a translucent electrode 120. The scattering layer 102 is a glass having a refractive index of 2.0. For taking notice of the relationship between the refractive index of the base material of the scattering layer 102 and the refractive index of the translucent electrode 103, the scattering layer 102 (102B) is composed of only a base material and does not contain a scattering material. The scattering material remains an important element for obtaining a high light extraction efficiency. The thickness of the scattering layer is sufficiently large as compared with the organic layer and translucent electrode and therefore, the thickness of the scattering layer is not taken into consideration. The translucent electrode 103 has a thickness of 0.1 to 0.8 μm and a refractive index of 1.96 to 2.2.

Here, the organic layer 110 and the translucent electrode 120 are regarded as an integrated body having a thickness of 0.15 μm and a refractive index of 2.0. The organic layer 110, though this is actually a laminate composed of a plurality of layers, is combined with the translucent electrode 103 to form a single layer so as to take notice of the relationship between the refractive index of the base material of the scattering layer 102 and the refractive index of the translucent electrode 103. The model envisaged as above is calculated using a BPM method (Beam Propagation Method), where the calculation wavelength is 470 nm, the mode of light allowed to enter the organic layer is Gaussian, the output monitor for outputting the calculation results monitors the intensity of light present in the translucent electrode, the calculation step is X=0.01 μm, Y=0.005 μm and Z=0.5 μm, and the calculation region is X: ±4 μm, Y: +4 μm or −2 μm and Z: +1,000 μm.

FIG. 11 is a view showing the simulation results. The ordinate axis of FIG. 11 indicates the energy amount of the waveguide mode in the translucent electrode 103, which is an amount corresponding to the extraction loss, and the abscissa axis indicates the refractive index of the translucent electrode 103. The legend shows the film thickness of the translucent electrode 103. As seen from the Figure, when the refractive index of the translucent electrode 103 is equal to or lower than the refractive index of the base material of the scattering layer, the loss by the waveguide mode is not observed, whereas when the refractive index of the translucent electrode 103 is higher than the refractive index of the base material of the scattering layer 102, as the refractive index difference (Δn) is increased, the loss becomes large. In the Figure, the data are oscillated by the effect of change in the electric field intensity of the light-receiving part Rc according to the conditions, but the above-described tendency remains. Also, in the case where the thickness of the translucent electrode is from 0.1 to 0.3 μm, the refractive index of the translucent electrode 103 generating a loss is 2.10, 2.06 and 2.04, respectively, but in the case where the thickness is larger than that, if the refractive index exceeds 2.0, a loss is produced. However, as long as Δn is 0.2 or less, even when the film thickness of the translucent electrode 103 is changed, the loss is 7% or less and the light scattering layer can keep a sufficiently high effect of improving light extraction.

Incidentally, the scattering layer is formed directly on a metal substrate as a reflective substrate but may be formed through a barrier layer, for example, by forming a silica thin film on the metal substrate by sputtering and then forming the scattering layer. However, by virtue of forming the scattering layer composed of a glass on the reflective substrate without the intervention of an adhesive or an organic layer, a very stable and flat surface can be obtained and moreover, thanks to the construction composed only of an inorganic substance, a thermally stable optical device with a long life time can be fabricated.

The characteristics of the scattering layer are described in detail below.

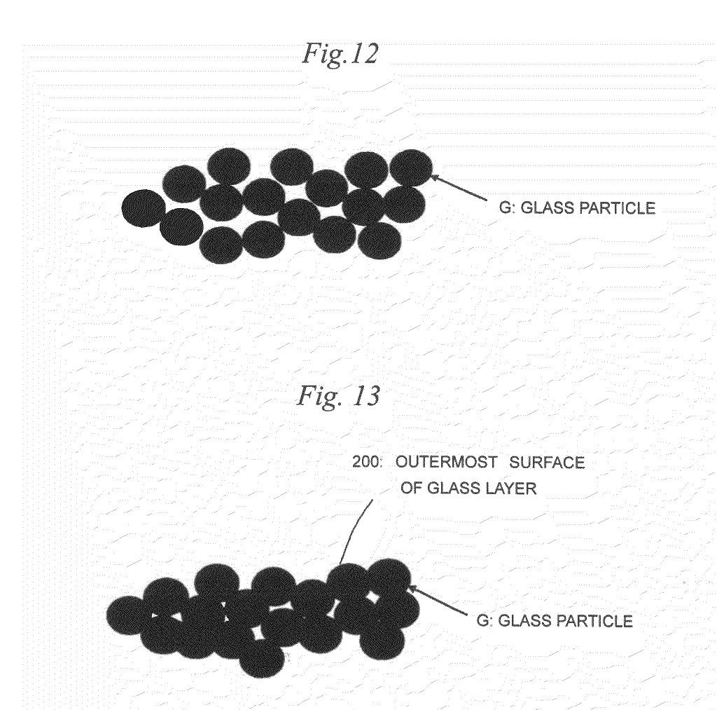

FIG. 12 shows, in the case of firing the glass powder, a conceptual view of a state of the glass powder coated by an appropriate method. In the Figure, a cross-section of the outermost portion of the glass layer as the scattering layer constituting the electrode-attached substrate of the present invention is shown. Such a state is obtained, for example, by dispersing glass particles G in a solvent or a mixture of a resin and a solvent and coating the dispersion to a desired thickness. For example, a glass particle G having a size of approximately from 0.1 to 10 μm in terms of the maximum length is used. In the case of mixing a resin and a solvent, a resin film having dispersed therein glass particles G is heated to decompose the resin, whereby the state of FIG. 12 is obtained. Although FIG. 12 is drawn in a simplified manner, a space is present between glass particles.

On the condition that the glass particle size of the glass particles G has distribution, a structure where a small glass particle enters the space between large glass particles G is considered to be formed. When the temperature is further raised, glass particles start fusing together at a temperature 10 to 20° C. lower than the softening temperature of the glass. A state at this time is shown in FIG. 13. After glass particles are fused together, the space formed between glass particles of FIG. 12 is deformed due to softening of the glass and a closed space is formed in the glass. In the outermost layer of the glass particle, an outermost surface of the scattering layer 102 (glass layer) is formed resulting from fusion of glass particles together. On the outermost surface, a space failing in turning into a closed space is present as a concave.

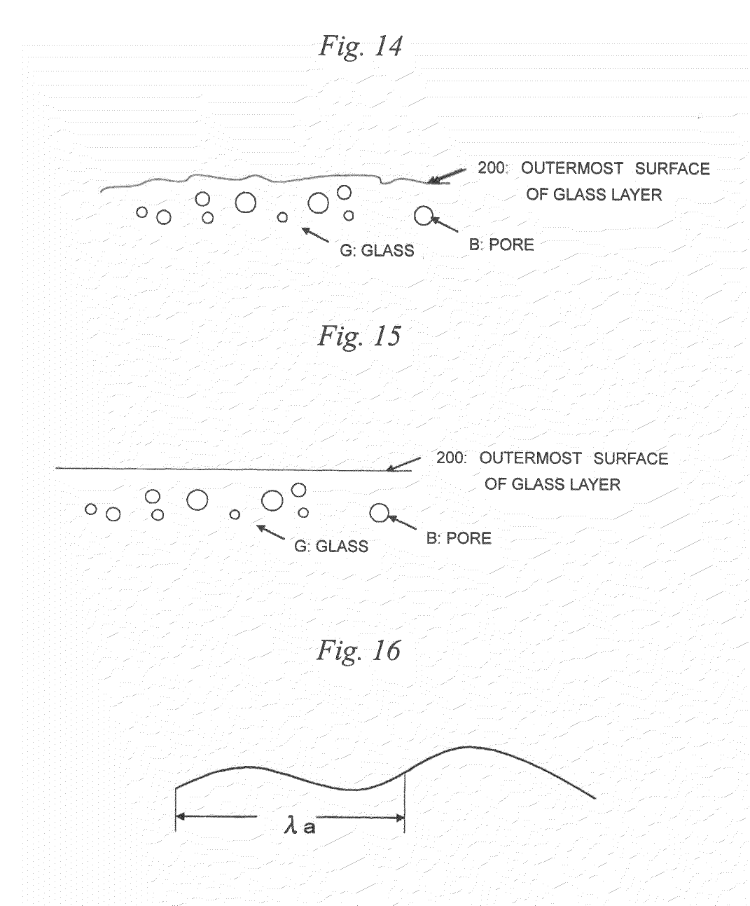

When the temperature is further raised, softening and fluidization of the glass proceed, and the space inside of the glass forms a spherical pore. On the glass outermost surface 200, the concave originated in the space between glass particles G is smoothed. This state is shown in FIG. 14. Not only a pore derived from a space between glass particles G is formed but also a pore is sometimes formed resulting from generation of a gas in the course of the glass being softened. For example, when an organic material is adhering to the glass layer surface, the organic material decomposes to generate CO₂ in some cases and a pore is thereby formed. Also, a pore may be positively formed by introducing such a thermally decomposable substance. This state is usually obtained in the vicinity of the softening temperature. The viscosity of the glass is as high as 10^{7.6} poises at the softening temperature and when the size of the pores is several μm or less, the pore cannot rise to the surface. Accordingly, the surface can be made smoother while keeping the pore from rising to the surface by adjusting the material composition so as to generate a small pore and at the same time, by further raising the temperature or prolonging the retention time. When the glass layer is cooled from the thus surface-smoothed state, as shown in FIG. 15, a scattering layer with a smooth surface, in which the density of the scattering material is smaller in the surface than in the inside of the scattering layer, is obtained.

In this way, generation of a pore or a concave in the outermost surface of the glass layer can be suppressed while allowing a pore to remain in the glass layer by adjusting the material composition and firing temperature for forming the glass layer. In other words, when the firing temperature profile and the firing temperature are adjusted so as to prevent the scattering material from rising but allow it to remain in the glass layer without rising to the surface, an electrode-attached substrate with excellent scattering characteristics and high surface smoothness can be provided.

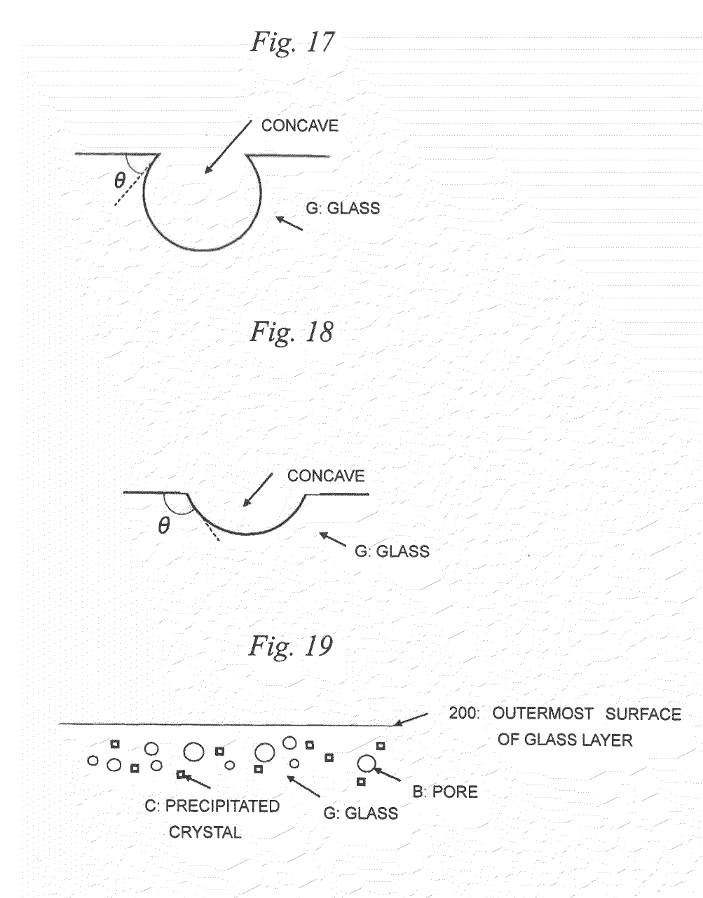

At this time, the outermost surface of the glass layer sometimes undulates depending on the treating temperature, the glass material for glass layer, the size of glass particle and the substrate material. A conceptual view thereof is shown in FIG. 16. The waviness as used herein indicates a waviness having a period λ of 10 μm or more. The size (roughness) of the waviness is approximately from 0.01 to 5 μm in terms of the waviness roughness Ra. Even when such a waviness is present, the microscopic smoothness, namely the microscopic surface roughness Ra, is kept at 30 nm or less. In the case where the treating temperature is low, a microscopic concave portion of the outermost surface may remain, but by taking a long firing time, the concave portion comes to have a gentle shape as shown in FIG. 18 but not an overhung shape shown in FIG. 17. The overhung shape as used herein means that the angle θ between the surface of the scattering layer and a tangent line in the vicinity of an opening of the concave portion is an acute angle as shown in FIG. 17, and the gentle shape means that θ in FIG. 18 is an obtuse angle or a right angle. In the case of a gentle shape as above, the possibility that the organic LED element causes an inter-electrode short circuiting due to the concave portion is likely to be low. The firing temperature is preferably higher than the glass transition temperature by approximately from 40 to 60° C. A too low temperature causes insufficient sintering, resulting in failure to smooth the surface. For this reason, the firing temperature is more preferably higher than the glass transition temperature by approximately from 50 to 60° C.

Further, use of the easily crystallizable glass makes it possible to precipitate crystals in the inside of the glass layer. At this time, when the crystals have a size of 0.1 μm or more, they act as a light scattering material. A state at this time is shown in FIG. 19. A suitable selection of the firing temperature makes it possible to precipitate the crystals in the inside of the glass layer while inhibiting the precipitation of the crystals in the outermost surface of the glass layer as described above. Specifically, it is desirable that the temperature is about 60° C. to about 100° C. higher than the glass transition temperature. On such an increase in temperature as this, the viscosity of the glass is high, and the pores do not rise to the surface.

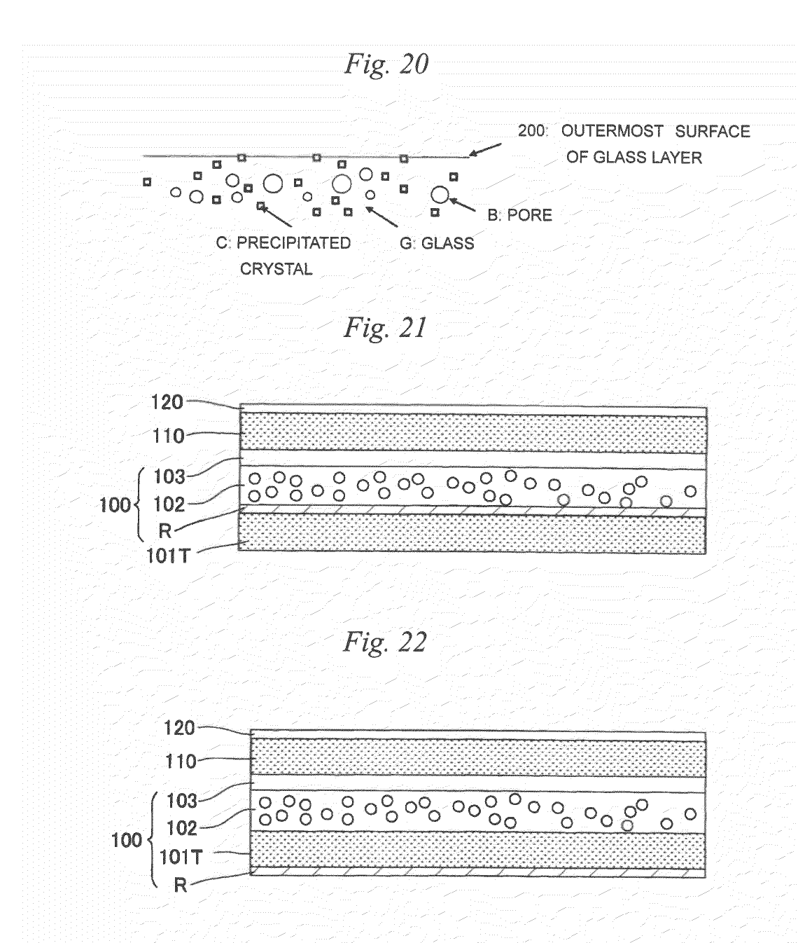

When the temperature is too high, the crystals also precipitate in the outermost surface of the glass layer to lose smoothness of the outermost surface. This is therefore unfavorable. A schematic view thereof is shown in FIG. 20. Accordingly, the firing temperature is more preferably about 60° C. to about 80° C. higher than the glass transition temperature, and most preferably about 60° C. to about 70° C. higher than the glass transition temperature. Such a technique makes it possible to allow the pores and the precipitated crystals to exist in the glass layer as the scattering material and to inhibit the generation thereof in the glass outermost surface. The reason why these are possible is that the glass is flattened for itself within the certain temperature range, and that high viscosity at which the pores do not rise to the surface can be realized or the crystals can be precipitated. In the case of a resin, it is difficult to control the process at high viscosity as described above, and also the crystals can not be precipitated.

As described above, the substrate in which the density of the scattering material in the outermost surface of the above-mentioned scattering layer is lower than the density of the scattering material in the inside of the above-mentioned scattering layer can be obtained by adjusting the material composition and the firing conditions. Further, it becomes possible to obtain the substrate having sufficient scattering characteristics and a smooth surface by using a substrate in which there is present such 6 that the density ρ₁ of the scattering material at a half thickness of the above-mentioned scattering layer including glass and the density ρ₂ of the scattering material at a distance x from a surface of the above-mentioned scattering layer on the side facing to the above-mentioned translucent electrode (namely, a surface on the substrate side), which satisfies δ/2<x≦δ, satisfy ρ₁≧ρ₂.

Furthermore, a surface waviness is sometimes formed in the scattering layer. In the case of having a waviness, as shown in FIG. 16, the ratio Ra/Rλa of the waviness roughness Ra of the scattering layer surface to the wavelength Rλa of the surface waviness is preferably from 1.0×10⁻⁴ to 3.0×10⁻².

The surface roughness Ra of the scattering layer surface is preferably 30 nm or less. More preferably, the surface roughness of the scattering layer is 10 nm or less.

For example, in the case of forming an organic LED element on such a substrate, a translucent electrode needs to be thinly formed and in order to enable forming the translucent electrode without being affected by the underlying layer, the surface roughness is 30 nm or less, preferably 10 nm or less. If the surface roughness exceeds 30 nm, the coatability of an organic layer formed thereon may deteriorate and short circuiting sometimes occurs between the translucent electrode formed on the glass scattering layer and the other electrode. The inter-electrode short circuiting brings about non-lighting of the element, but the lighting can be restored by applying an overcurrent in some cases. In view of enabling the restoration, the roughness of the glass scattering layer is preferably 10 nm or less, more preferably 3 nm or less.

Incidentally, it is known that in a certain material system, a surface roughness of 10 nm or less can be obtained when the firing temperature is set to 570° C. or more (see, Table 1). The optimal firing conditions vary depending on the material system, but by controlling the kind or size of the scattering material, it becomes possible to prevent the scattering material from being present in the outermost surface and obtain a scattering layer excellent in the surface smoothness.

TABLE 1

| | | | | | Surface | Diffuse |
|---|---|---|---|---|---|---|
| | | Ra | Rλa | Ra/Rλa | Area | Reflection |
| Glass Material | | (μm) | (μm) | (10⁻²) | Ratio | Ratio |
| A | Firing at 550° C. | 3.39 | 143 | 2.37 | 1.0352 | 98% |
| | Firing at 560° C. | 2.58 | 216 | 1.19 | 1.0111 | 85% |
| | Firing at 570° C. | 2.53 | 236 | 1.07 | 1.0088 | 83% |
| | Firing at 580° C. | 1.68 | 302 | 0.556 | 1.0027 | 60% |
| B | | 4.74 | 492 | 0.963 | 1.0082 | 72% |

| | | | | | |
|---|---|---|---|---|---|
| C | 0.04 | 171 | 0.0234 | 1.0001 | 38% |

Further, when the pores are present in the scattering layer, an increase in size of the pores increases buoyancy in a scattering layer forming process such as firing, resulting in an easy rising of the pores to the surface. When the pores reach the outermost surface, there is the possibility that they burst to significantly deteriorate the surface smoothness. Furthermore, the number of the scattering materials relatively decreases in that portion, so that scatterability decreases only in that portion. Coagulation of such large pores also results in visual observation as unevenness. Moreover, the ratio of the pores having a diameter of 5 μm or more is desirably 15 vol % or less, more desirably 10 vol % or less, and still more preferably 7 vol % or less. In addition, even when the scattering material is other than the pores, the number of the scattering materials relatively decreases in that portion, so that scatterability decreases only in that portion. Accordingly, the ratio of the scattering material having a maximum length of 5 μm or more is desirably 15 vol % or less, more desirably 10 vol % or less, and still more desirably 7 vol % or less.

The content of the scattering material in the scattering layer is preferably at least 1 vol %.

The experimental results reveal that when the scattering material is contained in an amount of 1 vol % or more, sufficient scattering property can be obtained.

Furthermore, there are the case where the scattering material is pores, the case where it is material particles having a composition different from that of the base material and the case where it is precipitated crystals of the base material. These may be used either alone or as a mixture thereof.

When the scattering material is pores, the size of the pores, pore distribution or density can be adjusted by adjusting the firing conditions such as the firing temperature.

When the scattering material is material particles having a composition different from that of the base material, the size, distribution or density of the scattering material can be adjusted by adjusting the material composition or the firing conditions such as the firing temperature.

When the above-mentioned scattering material is precipitated crystals of the glass constituting the above-mentioned base material, the size of the pores, pore distribution or density can be adjusted by adjusting the firing conditions such as the firing temperature.

Further, the first refractive index of the base material for at least one wavelength of wavelengths λ (430 nm<λ<650 nm) is desirably 1.8 or more. Although it is difficult to form a high refractive index material layer, it becomes easy to adjust the refractive index by adjusting the material composition of the glass material.

### Embodiment 2

### Another Construction Example of Organic LED Element

The organic LED element according to embodiment 2 of the present invention is described below by referring to the drawings. Incidentally, the same reference numerals as in FIG. 1 are given to the same constituents, and descriptions thereof are omitted. FIG. 21 is a cross-sectional view showing another structure of the organic LED element of the present invention. The another organic LED element of the present invention comprises a translucent electrode-attached substrate 100 in which a reflective film R composed of a silver layer is formed on a translucent glass substrate 101T, a scattering layer 102 composed of a glass layer is formed thereon, and a translucent electrode 103 composed of ITO is formed thereon. Other parts are formed in the same manner as in embodiment 1 and are not described here.

### Embodiment 3

### Still Another Construction Example of Organic LED Element

The organic LED element according to embodiment 3 of the present invention is described below by referring to the drawings. Incidentally, the same reference numerals as in FIG. 1 are given to the same constituents, and descriptions thereof are omitted. FIG. 22 is a cross-sectional view showing still another structure of the organic LED element of the present invention. The still another organic LED element of the present invention is different from that of embodiment 2 only in that a substrate fabricated by forming a reflective film R on the back side of a translucent glass substrate 101T is used as the translucent electrode-attached substrate 100, and other parts are formed in the same manner as in embodiment 2.

Respective members are described in detail below.

Substrate

The reflective substrate includes a substrate where the substrate itself is a reflective substrate, such as aluminum substrate, and a substrate where a reflective film is formed on a substrate. As for the former, a multilayer ceramic substrate such as ceramic, alumina, MgO, TiO₂, ZrO₂ and LTCC (LOW TEMPERATURE CO-FIRED CERAMICS), AlN, crystallized glass, metal, iron, copper, stainless steel and the like are applicable. As for the latter, those obtained by forming a reflective film such as Au, Ag, Cu, Al, Cr, Mo, Pt, W, Ni and Ru on a translucent substrate (e.g., glass substrate) or an opaque substrate are applicable. Above all, the substrate used is preferably a ceramic (heat resistance), more preferably alumina, MgO, TiO₂, ZrO₂ or LTCC (reflectivity), still more preferably alumina (heat conduction).

A dielectric multilayer film such as silica/titania multilayer film is also effective. Incidentally, in the case of using a translucent substrate, there may be considered two cases, that is, a case where the position of the reflective film is on the element side (top) and a case where the position is on the opposite side (bottom).

It is also possible to utilize the recurrent reflection of a glass bead by spreading glass beads on a substrate.

Of these substrate materials, in view of reflectivity, a material having a high reflectivity, such as Ag and Al, is preferred as the reflective substrate. Also, in consideration of heat resistance, the substrate is preferably a ceramic. Furthermore, taking account the heat conduction, use of alumina is preferred. In addition, when mounting workability is taken into consideration, for example, a multilayer ceramic substrate such as LTCC with a thermal via is applicable.

In the case where the position of the reflective film is not on the element side but is on the side opposite the element, a substrate composed of a material having a high transmittance for visible light, mainly a glass substrate or the like, is used as the translucent substrate 101. The material of the glass substrate includes an inorganic glass such as alkali glass, non-alkali glass and quartz glass. The thickness of the translucent substrate 101 is preferably from 0.1 to 2.0 mm in the case of glass. However, if the thickness is too small, the strength decreases. Accordingly, the thickness is more preferably from 0.5 to 1.0 mm.

Incidentally, in preparing the scattering layer by glass frit, a problem of strain or the like is caused. Accordingly, the thermal expansion coefficient is preferably 50×10⁻⁷/° C. or more, more preferably 70×10⁻⁷/° C. or more, still more preferably 80×10⁻⁷/° C. or more.

Also, it is preferred that the average thermal expansion coefficient of the scattering layer at 100 to 400° C. is from 70×10⁻⁷ to 95×10⁻⁷ (° C.⁻¹) and at the same time, the glass transition temperature is from 450 to 550° C.

Scattering Layer

The construction, production method and characteristics of the scattering layer and the method for measuring the refractive index are described in detail below. Incidentally, in order to realize the enhancement of light extraction efficiency, which is the principal object of the present invention, the refractive index of the scattering layer is preferably equal to or higher than the refractive index of the translucent electrode material, and this is described in detail later.

Construction

In this embodiment, as described above, the scattering layer 102 is formed by forming a glass powder on a glass substrate by coating or the like method and then firing the glass powder at a desired temperature and comprises a base material 105 having a first refractive index and a plurality of scattering materials 104 being dispersed in the base material 105 and having a second refractive index different from the refractive index of the base material, where the intralayer distribution of the scattering materials in the scattering layer decreases from the inside of the scattering layer to the outermost surface. By virtue of using the glass layer, as described above, smoothness of the surface can be maintained while having excellent scattering characteristics and when the glass layer is used on the light exit surface side of a light-emitting device or the like, remarkably high-efficient light extraction can be realized.

As for the scattering layer, a material (base material) having a coated main surface and having a high light transmittance is used, and a glass, a crystallized glass, a translucent resin or a translucent ceramic is used as the base material. The material for the glass includes an inorganic glass such as soda lime glass, borosilicate glass, non-alkali glass and quartz glass. Incidentally, a plurality of scattering materials 104 (for example, a pore, a precipitated crystal, a material particle different from the base material, or a phase-separated glass) are formed inside of the base material. The “particle” as used herein indicates a small solid substance, and examples thereof include a filler and a ceramic. Also, the “pore” indicates an air or gas material. Furthermore, the “phase-separated glass” means a glass composed of two or more kinds of glass phases. Here, when the scattering material is a pore, the diameter of the scattering material means the length of a void.

In order to realize the enhancement of light extraction efficiency, which is the principal object of the invention, the refractive index of the base material is preferably equal to or higher than the refractive index of the translucent electrode material. This is because if the refractive index is low, a loss due to total reflection occurs at an interface between the base material and the translucent electrode material. The refractive index of the base material may be sufficient if it is higher at least in one part (for example, red, blue or green) of the emission spectrum range of the scattering layer, but the refractive index of the base material is preferably higher over the entire region (from 430 to 650 nm) of the emission spectrum range, more preferably over the entire region (from 360 to 830 nm) of the wavelength range of visible light.

In order to prevent the inter-electrode short circuiting of the organic LED element, the main surface of the scattering layer needs to be smooth. For this purpose, it is not preferred that the scattering material protrudes from the main surface of the scattering layer. From the standpoint of preventing protrusion of the scattering material from the main surface of the scattering layer, it is preferred that a scattering material is not present within 0.2 μM from the main surface of the scattering layer. The arithmetic mean roughness (Ra) of the main surface of the scattering layer as specified in JIS B0601-1994 is preferably 30 nm or less, more preferably 10 nm or less (see Table 1), still more preferably 1 nm or less. Both the refractive index of the scattering material and the refractive index of the base material may be high, but the refractive index difference (Δn) is preferably 0.2 or more at least in one part of the emission spectrum range of the light-emitting layer. In order to obtain sufficient scattering characteristics, the refractive index difference (Δn) is more preferably 0.2 or more over the entire region (from 430 to 650 nm) of the emission spectrum range or the entire region (from 360 to 830 nm) of the wavelength range of visible light.

In view of obtaining a maximum refractive index difference, it is preferred to take a construction where the material having high light transmittance is a high refractive index glass and the scattering material is a gas material, that is, a pore. In this case, the refractive index of the base material is preferably as high as possible and therefore, a high refractive index glass is preferably used as the base material. As for the components of the high refractive index glass, there may be used a high refractive index glass where one kind or two or more kinds of components selected from P₂O₅, SiO₂, B₂O₃, Ge₂O and TeO₂ are contained as the network former and one kind or two or more kinds of components selected from TiO₂, Nb₂O₅, WO₃, Bi₂O₃, La₂O₃, Gd₂O₃, Y₂O₃, ZrO₂, ZnO, BaO, PbO and Sb₂O₃ are contained as the high refractive index component. In addition, in terms of adjusting the characteristics of the glass, an alkali oxide, an alkaline earth oxide, a fluoride or the like may be used within the range not impairing properties required of the refractive index. Specific examples of the glass system include a B₂O₃—ZnO—La₂O₃ system, a P₂O₅—B₂O₃—R′₂O—R″O—TiO₂—Nb₂O₅—WO₃—Bi₂O₃ system, a TeO₂—ZnO system, a B₂O₃—Bi₂O₃ system, a SiO₂—Bi₂O₃ system, a SiO₂—ZnO system, a B₂O₃—ZnO system and a P₂O₅—ZnO system, wherein R′ represents an alkali metal element and R″ represents an alkaline earth metal element. These are merely examples, and the construction is not limited to these examples as long as it satisfies the above-described conditions.

The color of light emission can be changed by allowing the base material to have a specific transmittance spectrum. As for the colorant, one of known colorants such as transition metal oxide, rare earth metal oxide and metal colloid can be used alone, or some of them may be used in combination.

Here, in general, white light emission is necessary for backlight or lighting application. Known methods for whitening include a method of spatially selectively coating red, blue and green areas (selective coating method), a method of laminating light-emitting layers having different light emission colors (lamination method), and a method of color-converting light emitted in blue with a color-converting material spatially separately provided (color conversion method). In the backlight or lighting application, what is necessary is just to uniformly obtain white color and therefore, a lamination method is generally employed. The light-emitting layers laminated are combined to produce white color by additive color mixing. For example, there is a case of laminating blue-green and orange layers or laminating red, blue and green layers. Above all, in the lighting application, color reproducibility on the irradiated surface is important, and it is preferred to have an emission spectrum necessary for the visible light region. In the case of laminating a blue-green layer and an orange layer, if lighting is effected using a laminate containing a green component in a large proportion, color reproducibility deteriorates because of low light emission intensity of green color. The lamination method is advantageous in that the color arrangement need not be spatially changed, but, on the other hand, this method has the following two problems. The first problem is that the emitted light extracted is affected by interference, because the film thickness of the organic layer is small as described above. Accordingly, the color tint changes according to the viewing angle. In the case of white color, such a phenomenon sometimes becomes a problem due to high sensitivity of the human eye to color tint. The second problem is that the carrier balance is disrupted during light emission and the light-emitting luminance changes in each color to cause a change in the color tint.

The conventional organic LED element has no idea of dispersing a fluorescent material in a scattering layer or a diffusing layer and in turn, cannot solve the problem of a change in the color tint. Accordingly, the conventional organic LED element is insufficient for the backlight or lighting application. However, the substrate for an organic LED element and the organic LED element of the present invention allow for use of a fluorescent material in the scattering material or base material, and this can produce an effect of performing wavelength conversion by light emission from the organic layer and thereby changing the color tint. In this case, the light emission colors of the organic LED can be decreased and since the emitted light exits after being scattered, the angle dependency of color tint and the change with aging of color tint can be suppressed.

Production Method of Scattering Layer

The scattering layer is produced by coating and firing, but in particular, from the standpoint of uniformly and rapidly forming a thick film of 10 to 100 μM with a large area, a method of producing the layer by forming the glass into a frit paste is preferred. In utilizing the fit paste method, for suppressing thermal deformation of the substrate glass, it is preferred that the softening point (Ts) of the glass of the scattering layer is lower than the strain point (SP) of the substrate glass and at the same time, the difference in the thermal expansion coefficient α is small. The difference between the softening point and the strain point is preferably 30° C. or more, more preferably 50° C. or more. Also, the difference in the expansion coefficient between the scattering layer and the reflective substrate is preferably ±10×10⁻⁷ (1/K) or less, more preferably ±5×10⁻⁷ (1/K) or less. The “frit paste” indicates a paste where a glass powder is dispersed in a resin, a solvent, a filler or the like. The frit paste is patterned using a pattern forming technique such as screen printing and fired, whereby glass layer coating can be performed. The technical outline is described below.

Frit Paste Material

### 1. Glass Powder

The particle diameter of the glass powder is from 1 to 10 μm. In order to control thermal expansion of the fired film, a filler is sometimes added. Specific examples of the filler include zircon, silica and alumina. The particle diameter of the filler is from 0.1 to 20 μm.

The glass material is described below.

In the present invention, the scattering layer uses a glass material containing from 20 to 30 mol % of P₂O₅, from 3 to 14 mol % of B₂O₃, from 10 to 20 mol % in total of Li₂O, Na₂O and K₂O, from 10 to 20 mol % of Bi₂O₃, from 3 to 15 mol % of TiO₂, from 10 to 20 mol % of Nb₂O₅ and from 5 to 15 mol % of WO₃, with the total amount of these components being 90 mol % or more.

The glass composition for forming the scattering layer is not particularly limited as long as desired scattering characteristics are obtained and the glass can be formed into a fit past and fired, but in order to maximize the extraction efficiency, examples of the glass composition include a system containing P₂O₅ as an essential component and further containing one or more components of Nb₂O₅, Bi₂O₃, TiO₂ and WO₃; a system containing B₂O₃, ZnO and La₂O₃ as essential components and containing one or more components of Nb₂O₅, ZrO₂, Ta₂O₅ and WO₃; a system containing SiO₂ as an essential component and containing one or more components of Nb₂O₅ and TiO₂; and a system containing Bi₂O₃ as a main component and containing SiO₂, B₂O₃ or the like as a network forming component.

Incidentally, in all of the glass systems for use as the scattering layer in the present invention, As₂O₃, PbO, CdO, ThO₂ and HgO that are components having an adverse effect on the environment are not contained except for inevitable mingling as an impurity derived from a raw material.

The scattering layer containing P₂O₅ and containing one or more components of Nb₂O₅, Bi₂O₃, TiO₂ and WO₃ is preferably a glass within the composition range of, in terms of mol %, from 15 to 30% of P₂O₅, from 0 to 15% of SiO₂, from 0 to 18% of B₂O₃, from 5 to 40% of Nb₂O₅, from 0 to 15% of TiO₂, from 0 to 50% of WO₃, from 0 to 30% of Bi₂O₃, provided that Nb₂O₅+TiO₂+WO₃+Bi₂O₃ is from 20 to 60%, from 0 to 20% of Li₂O, from 0 to 20% of Na₂O, from 0 to 20% of K₂O, provided that Li₂O+Na₂O+K₂O is from 5 to 40%, from 0 to 10% of MgO, from 0 to 10% of CaO, from 0 to 10% of SrO, from 0 to 20% of BaO, from 0 to 20% of ZnO and from 0 to 10% of Ta₂O₅.

The effects of respective components are, in terms of mol %, as follows.

P₂O₅ is an essential component that forms a skeleton of this glass system and performs vitrification. If its content is too small, the devitrification of glass is intensified and a glass cannot be obtained. Accordingly, the content is preferably 15% or more, more preferably 18% or more. On the other hand, if the content is too large, the refractive index decreases and the object of the invention cannot be achieved. Accordingly, the content of this component is preferably 30% or less, more preferably 28% or less

B₂O₃ is an optional component, and this component when added into the glass enhances the devitrification resistance and decreases the thermal expansion coefficient. If its content is too large, the refractive index decreases. Accordingly, the content of this component is preferably 18% or less, more preferably 15% or less.

SiO₂ is an optional component, and this component when added in a slight amount stabilizes the glass and enhance the devitrification resistance. If its content is too large, the refractive index decreases. Accordingly, the content of this component is preferably 15% or less, more preferably 10% or less, still more preferably 8% or less.

Nb₂O₅ is an essential component that enhances the refractive index and at the same time, has an effect of raising the weather resistance. The content thereof is preferably 5% or more, more preferably 8% or more. On the other hand, if its content is too large, devitrification increases and a glass cannot be obtained. Accordingly, the content of this component is preferably 40% or less, more preferably 35% or less.

TiO₂ is an optional component that enhances the refractive index. If its content is too large, the coloring of glass is intensified to bring about a large loss in the scattering layer and the object of enhancing the light extraction efficiency cannot be achieved. Accordingly, the content of this component is preferably 15% or less, more preferably 13% or less.

WO₃ is an optional component that enhances the refractive index and decreases the glass transition temperature and in turn, the firing temperature. If this component is introduced in excess, the glass is colored to bring about a decrease in the light extraction efficiency. Accordingly, the content thereof is preferably 50% or less, more preferably 45% or less.

Bi₂O₃ is a component that enhances the refractive index, and can be introduced into the glass in a relatively large amount while keeping the stability of glass. However, its introduction in excess causes a problem that the glass is colored and the transmittance decreases. Accordingly, the content of this component is preferably 30% or less, more preferably 25% or less.

In order to increase the refractive index more than the desired value, one or more components of Nb₂O₅, TiO₂, WO₃ and Bi₂O₃ must be necessarily contained. Specifically, the content of (Nb₂O₅+TiO₂+WO₃+Bi₂O₃) is preferably 20% or more, more preferably 25% or more. On the other hand, if the content of these components is too large, coloring or too strong devitrification occurs. Accordingly, the content is preferably 60% or less, more preferably 55% or less.

Ta₂O₅ is an optional component that enhances the refractive index. If the amount added of this component is too large, the devitrification resistance decreases and in addition, this component is expensive. Accordingly, the content thereof is preferably 10% or less, more preferably 5% or less.

The alkali metal oxide (R₂O) such as Li₂O, Na₂O and K₂O has an effect of enhancing the meltability and decreasing the glass transition temperature and at the same time, has an effect of increasing the affinity for the glass substrate and strengthening the adherence. For this reason, it is preferred to contain one kind or two or more kinds of these oxides. The alkali metal oxide is preferably contained in an amount of, in terms of the content of (Li₂O+Na₂O+K₂O), preferably 5% or more, more preferably 10% or more. However, if the alkali metal oxide is contained in excess, the stability of glass is impaired and in addition, since all are a component that decreases the refractive index, the refractive index of the glass decreases, making it impossible to expect the desired enhancement of the light extraction efficiency. Accordingly, the total content is preferably 40% or less, more preferably 35% or less.

Li₂O is a component for decreasing the glass transition temperature and enhancing the solubility. If its content is too large, devitrification is excessively intensified and a homogeneous glass cannot be obtained. Also, the thermal expansion coefficient becomes excessively high and the difference in the expansion coefficient from the substrate increases. At the same time, the refractive index decreases and the desired enhancement of the light extraction efficiency cannot be achieved. Accordingly, the content of this component is preferably 20% or less, more preferably 15% or less.

Both Na₂O and K₂O are an optional component that enhances the meltability. However, their excessive inclusion causes a decrease in the refractive index and in turn, the desired light extraction efficiency cannot be achieved. Accordingly, the content of each component is preferably 20% or less, more preferably 15% or less.

ZnO is a component that enhances the refractive index and decreases the glass transition temperature. However, if this component is added in excess, the devitrification of glass is intensified and a homogeneous glass cannot be obtained. Accordingly, the content of this component is preferably 20% or less, more preferably 18% or less.

BaO is a component that enhances the refractive index and at the same time, enhances the solubility. However, if added in excess, the stability of glass is impaired. Accordingly, the content of this component is preferably 20% or less, more preferably 18% or less.

MgO, CaO and SrO are an optional component that enhances the solubility but at the same time, decreases the refractive index. Accordingly, the contents of all these components are preferably 10% or less, more preferably 8% or less.

In order to obtain high refractive index and stable glass, the content of the above-described components is preferably 90% or more, more preferably 93% or more, still more preferably 95% or more.

In addition to the components described above, a refining agent, a vitrification promoting component, a refractive index adjusting component, a wavelength converting component or the like may be added each in a small amount within the range not impairing necessary glass characteristics. Specifically, examples of the refining agent include Sb₂O₃ and SnO₂, examples of the vitrification promoting component include GeO₂, Ga₂O₃ and In₂O₃, examples of the refractive index adjusting component include ZrO₂, Y₂O₃, La₂O₃, Gd₂O₃ and Yb₂O₃, and examples of the wavelength converting component include a rare earth component such as CeO₂, Eu₂O₃ and Er₂O₃.

The scattering layer containing B₂O₃ and La₂O₃ as essential components and containing one or more components of Nb₂O₅, ZrO₂, Ta₂O₅ and WO₃ is preferably a glass within the composition range of, in terms of mol %, from 20 to 60% of B₂O₃, from 0 to 20% of SiO₂, from 0 to 20% of Li₂O, from 0 to 10% of Na₂O, from 0 to 10% of K₂O, from 5 to 50% of ZnO, from 5 to 25% of La₂O₃, from 0 to 25% of Gd₂O₃, from 0 to 20% of Y₂O₃, from 0 to 20% of Yb₂O₃, provided that La₂O₃+Gd₂O₃+Y₂O₃+Yb₂O₃ is from 5 to 30%, from 0 to 15% of ZrO₂, from 0 to 20% of Ta₂O₅, from 0 to 20% of Nb₂O₅, from 0 to 20% of WO₃, from 0 to 20% of Bi₂O₃ and from 0 to 20% of BaO.

The effects of respective components are, in terms of mol %, as follows.

B₂O₃ is a network forming oxide and is an essential component in this glass system. If its content is too small, a glass is not formed or the devitrification resistance of glass decreases. Accordingly, this component is preferably contained in an amount of 20% or more, more preferably 25% or more. On the other hand, if the content is too large, the refractive index decreases and furthermore, reduction in the resistance is incurred. Accordingly, the content thereof is restricted to 60% or less, preferably 55% or less.

SiO₂ is a component that enhances the stability of glass when added into the glass of this system. However, if the amount of this component introduced is too large, a decrease in the refractive index or a rise of the glass transition temperature is brought about. For this reason, the content thereof is preferably 20% or less, more preferably 18% or less.

Li₂O is a component that decreases the glass transition temperature. However, if the amount of this component introduced is too large, the devitrification resistance of glass decreases. For this reason, the content thereof is preferably 20% or less, more preferably 18% or less.

Na₂O and K₂O enhance the solubility, but their introduction causes a reduction of the devitrification resistance or a decrease in the refractive index. Accordingly, the content of each component is preferably 10% or less, more preferably 8% or less.

ZnO is an essential component that enhances the refractive index of glass and at the same time, decreases the glass transition temperature. For this reason, the amount of this component introduced is preferably 5% or more, more preferably 7% or more. On the other hand, if the amount added is too large, the devitrification resistance decreases and a homogeneous glass cannot be obtained. Accordingly, the content thereof is preferably 50% or less, more preferably 45% or less.

La₂O₃ is an essential component that achieves a high refractive index and enhances the weather resistance when introduced into the B₂O₃-system glass. For this reason, the amount of this component introduced is preferably 5% or more, more preferably 7% or more. On the other hand, if the amount introduced is too large, a rise of the glass transition temperature or a decrease in the devitrification resistance of glass is incurred and a homogeneous glass cannot be obtained. Accordingly, the content thereof is preferably 25% or less, more preferably 22% or less.

Gd₂O₃ is a component that achieves a high refractive index, enhances the weather resistance when introduced into the B₂O₃-system glass, and improves the stability of glass when allowed to coexist with La₂O₃. However, if the amount of this component introduced is too large, the stability of glass decreases. Accordingly, the content thereof is preferably 25% or less, more preferably 22% or less.

Y₂O₃ and Yb₂O₃ are a component that achieves a high refractive index, enhances the weather resistance when introduced into the B₂O₃-system glass, and improves the stability of glass when allowed to coexist with La₂O₃. However, if the amount of these components introduced is too large, the stability of glass decreases. Accordingly, the content of each component is preferably 20% or less, more preferably 18% or less.

Rare earth oxides such as La₂O₃, Gd₂O₃, Y₂O₃ and Yb₂O₃ are a component essential for achieving a high refractive index and enhancing the weather resistance of glass. Accordingly, the total amount of these components, La₂O₃+Gd₂O₃+Y₂O₃+Yb₂O₃, is preferably 5% or more, more preferably 8% or more. However, if the amount introduced is too large, the devitrification resistance of glass decreases and a homogeneous glass cannot be obtained. Accordingly, the content thereof is preferably 30% or less, more preferably 25% or less.

ZrO₂ is a component for enhancing the refractive index. However, if its content is too large, the devitrification resistance decreases or the liquid-phase temperature rises excessively. Accordingly, the content of this component is preferably 15% or less, more preferably 10% or less.

Ta₂O₅ is a component for enhancing the refractive index. However, if its content is too large, the devitrification resistance decreases or the liquid-phase temperature rises excessively. Accordingly, the content of this component is preferably 20% or less, more preferably 15% or less.

Nb₂O₅ is a component for enhancing the refractive index. However, if its content is too large, the devitrification resistance decreases or the liquid-phase temperature rises excessively. Accordingly, the content of this component is preferably 20% or less, more preferably 15% or less.

WO₃ is a component for enhancing the refractive index. However, if its content is too large, the devitrification resistance decreases or the liquid-phase temperature rises excessively. Accordingly, the content of this component is preferably 20% or less, more preferably 15% or less.

Bi₂O₃ is a component for enhancing the refractive index. However, if its content is too large, the devitrification resistance decreases, or coloring occurs in the glass to cause a decrease in the refractive index, resulting in a reduction of the extraction efficiency. Accordingly, the content of this component is preferably 20% or less, more preferably 15% or less.

BaO is a component for improving the refractive index. However, when the content is too large, resistance to devitrification decreases. Accordingly, it is preferably 20% or less, and more preferably 15% or less.

In order to conform to the object of the invention, the content of the components described above is preferably 90% or more, more preferably 95% or more. Even a component other than the above-described components may be added within the range not impairing the advantages of the present invention for the purposes of enhancing the clarity or solubility. Examples of such a component include Sb₂O₃, SnO₂, MgO, CaO, SrO, GeO₂, Ga₂O₃, In₂O₃ and fluorine.

The scattering layer containing SiO₂ as an essential component and containing one or more components of Nb₂O₅, TiO₂ and Bi₂O₃ is preferably a glass within the composition range of, in terms of mol %, from 20 to 50% of SiO₂, from 0 to 20% of B₂O₃, from 1 to 20% of Nb₂O₅, from 1 to 20% of TiO₂, from 0 to 15% of Bi₂O₃, from 0 to 15% of ZrO₂, provided that Nb₂O₅+TiO₂+Bi₂O₃+ZrO₂ is from 5 to 40%, from 0 to 40% of Li₂O, from 0 to 30% of Na₂O, from 0 to 30% of K₂O, provided that Li₂O+Na₂O+K₂O is from 1 to 40%, from 0 to 20% of MgO, from 0 to 20% of CaO, from 0 to 20% of SrO, from 0 to 20% of BaO and from 0 to 20% of ZnO.

SiO₂ is an essential component that acts as a network former for forming a glass. If its content is too small, a glass is not formed. Accordingly, the content of this component is preferably 20% or more, more preferably 22% or more. On the other hand, if its content exceeds 50%, the refractive index decreases and the glass transition temperature rises, and therefore, the content of this component is preferably 50% or less.

B₂O₃ assists in glass formation and decreases devitrification when added in a relatively small amount together with SiO₂. If its content is too large, the refractive index decreases. Accordingly, the content of this component is preferably 20% or less, more preferably 18% or less.

Nb₂O₅ is an essential component for enhancing the refractive index, and its content is preferably 1% or more, more preferably 3% or more. However, if this component is added in excess, the devitrification resistance of glass decreases and a homogeneous glass cannot be obtained. Accordingly, the content thereof is preferably 20% or less, more preferably 18% or less.

TiO₂ is an essential component for enhancing the refractive index, and its content is preferably 1% or more, more preferably 3% or more. However, if this component is added in excess, the devitrification resistance of glass decreases, making it impossible to obtain a homogeneous glass, and furthermore, coloring is caused to increase a loss due to absorption during propagation of light through the scattering layer. For this reason, the content thereof is preferably 20% or less, more preferably 18% or less.

Bi₂O₃ is an component for enhancing the refractive index. However, if this component is added in excess, the devitrification resistance of glass decreases, making it impossible to obtain a homogeneous glass, and moreover, coloring is caused to increase a loss due to absorption during propagation of light through the scattering layer. For this reason, the content thereof is preferably 15% or less, more preferably 12% or less.

ZrO₂ is a component that enhances the refractive index without deteriorating the degree of coloring. However, if its content is too large, the devitrification resistance of glass decreases and a homogeneous glass cannot be obtained. For this reason, the content of this component is preferably 15% or less, more preferably 10% or less.

In order to obtain a high refractive index glass, the total amount of Nb₂O₅+TiO₂+Bi₂O₃+ZrO₂ is preferably 5% or more, more preferably 8% or more. On the other hand, if this total amount is too large, the devitrification resistance of glass decreases or coloring occurs. Accordingly, the total amount is preferably 40% or less, more preferably 38% or less.

Li₂O, Na₂O and K₂O are a component that enhances the solubility and decreases the glass transition temperature, and moreover, these are a component that increases the affinity for the glass substrate. Accordingly, the total amount of these components, Li₂O+Na₂O+K₂O, is preferably 1% or more, more preferably 3% or more. On the other hand, if the content of the alkali oxide components is too large, the devitrification resistance of glass decreases and a homogeneous glass cannot be obtained. For this reason, the content thereof is preferably 40% or less, more preferably 35% or less.

BaO is a component that enhances the refractive index and at the same time, improves the solubility. However, if this component it contained in excess, the stability of glass is impaired and a homogeneous glass cannot be obtained. Accordingly, the content thereof is preferably 20% or less, more preferably 15% or less.

MgO, CaO, SrO and ZnO are a component that enhances the solubility of glass and when these components are added appropriately, the devitrification resistance of glass can be reduced. However, if they are contained in excess, devitrification is intensified and a homogeneous glass cannot be obtained. Accordingly, the content of each component is preferably 20% or less, more preferably 15% or less.

In order to conform to the object of the invention, the total amount of the components described above is preferably 90% or more. Furthermore, even a component other than the above-described components may be added within the range not impairing the advantages of the present invention for the purposes of enhancing the clarity, solubility or the like. Examples of such a component include Sb₂O₃, SnO₂, GeO₂, Ga₂O₃, In₂O₃, WO₃, Ta₂O₅, La₂O₃, Gd₂O₃, Y₂O₃ and Yb₂O₃.

The scattering layer containing Bi₂O₃ as a main component and containing SiO₂, B₂O₃ or the like as a glass forming aid is preferably a glass within the composition range of, in terms of mol %, from 10 to 50% of Bi₂O₃, from 1 to 40% of B₂O₃, from 0 to 30% of SiO₂, provided that B₂O₃+SiO₂ is from 5 to 40%, from 0 to 20% of P₂O₅, from 0 to 15% of Li₂O, from 0 to 15% of Na₂O, from 0 to 15% of K₂O, from 0 to 20% of TiO₂, from 0 to 20% of Nb₂O₅, from 0 to 20% of TeO₂, from 0 to 10% of MgO, from 0 to 10% of CaO, from 0 to 10% of SrO, from 0 to 10% of BaO, from 0 to 10% of GeO₂ and from 0 to 10% of Ga₂O₃.

The effects of respective components are, in terms of mol %, as follows.

Bi₂O₃ is an essential component that achieves a high refractive index and stably forms a glass even when introduced in a large amount. Accordingly, its content is preferably 10% or more, more preferably 15% or more. On the other hand, if this component is added in excess, coloring is caused in the glass to allow for absorption of light which should be originally transmitted, resulting in a decrease in the extraction efficiency, and additionally, devitrification is intensified, making it impossible to obtain a homogeneous glass. For this reason, the content thereof is preferably 50% or less, more preferably 45% or less.

B₂O₃ is an essential component that acts as a network former in a glass containing a large amount of Bi₂O₃ and assists in glass formation, and its content is preferably 1% or more, more preferably 3% or more. However, if the amount of this component added is too large, the refractive index of glass decreases. Accordingly, the content thereof is preferably 40% or less, more preferably 38% or less.

SiO₂ is a component that acts to assist in glass formation using Bi₂O₃ as a network former. However, if its content is too large, the refractive index decreases. Accordingly, the content of this component is preferably 30% or less, more preferably 25% or less.

B₂O₃ and SiO₂ enhance the glass formation when combined. Accordingly, the total amount thereof is preferably 5% or more, more preferably 10% or more. On the other hand, if the total amount of these components introduced is too large, the refractive index decreases. For this reason, the total amount thereof is preferably 40% or less, more preferably 38% or less.

P₂O₅ is a component that assists in glass formation and prevents the coloring degree from worsening. However, if its content is too large, the refractive index decreases. Accordingly, the content of this component is preferably 20% or less, more preferably 18% or less.

Li₂O, Na₂O and K₂O are a component for enhancing the glass solubility and furthermore, decreasing the glass transition temperature. However, if these components are contained in excess, the devitrification resistance decreases and a homogeneous glass cannot be obtained. Accordingly, the content of each component is preferably 15% or less, more preferably 13% or less. Also, if the total amount of the above-described alkali oxide components, Li₂O+Na₂O+K₂O, is too large, the refractive index decreases and furthermore, the devitrification resistance of glass decreases. Accordingly, the content thereof is preferably 30% or less, more preferably 25% or less.

TiO₂ is a component that enhances the refractive index. However, if its content is too large, coloring occurs or the devitrification resistance decreases and a homogeneous glass cannot be obtained. Accordingly, the content of this component is preferably 20% or less, more preferably 18% or less.

Nb₂O₅ is a component that enhances the refractive index. However, if the amount of this component introduced is too large, the devitrification resistance of glass decreases and a stable glass cannot be obtained. Accordingly, the content thereof is preferably 20% or less, more preferably 18% or less.

TeO₂ is a component that enhances the refractive index without worsening the coloring degree. However, if this component is introduced in excess, the devitrification resistance decreases, giving rise to coloring when the glass is fritted and then fired. Accordingly, the content thereof is preferably 20% or less, more preferably 15% or less.

GeO₂ is a component that enhances the stability of glass while keeping the refractive index relatively high. However, this component is very expensive and therefore, its content is preferably 10% or less, more preferably 8% or less. It is still more preferred not to contain the component.

Ga₂O₃ is a component that enhances the stability of glass while keeping the refractive index relatively high. However, this component is very expensive and therefore, its content is preferably 10% or less, more preferably 8% or less. It is still more preferred not to contain the component.

In order to conform to the object of the invention, the total amount of the components described above is preferably 90% or more, more preferably 95% or more. Even a component other than the above-described components may be added within the range not impairing the advantages of the present invention for the purposes of, for example, enhancing the clarity or solubility or adjusting the refractive index. Examples of such a component include Sb₂O₃, SnO₂, In₂O₃, ZrO₂, Ta₂O₅, WO₃, La₂O₃, Gd₂O₃, Y₂O₃, Yb₂O₃ and Al₂O₃.

The glass composition for forming the scattering layer is not particularly limited as long as desired scattering characteristics are obtained and the glass can be formed into a frit paste and fired, but in order to maximize the extraction efficiency, examples of the glass composition include a system containing P₂O₅ and further containing one or more components of Nb₂O₅, Bi₂O₃, TiO₂ and WO₃; a system containing B₂O₃ and La₂O₃ as essential components and containing one or more components of Nb₂O₅, ZrO₂, Ta₂O₅ and WO₃; a system containing SiO₂ as an essential component and containing one or more components of Nb₂O₅ and TiO₂; and a system containing Bi₂O₃ as a main component and containing SiO₂, B₂O₃ or the like as a glass forming aid. Incidentally, in all of the glass systems for use as the scattering layer in the present invention, As₂O₃, PbO, CdO, ThO₂ and HgO that are components having an adverse effect on the environment should not be contained except for inevitable mingling as an impurity derived from a raw material.

As for the system containing P₂O₅ and containing one or more components of Nb₂O₅, Bi₂O₃, TiO₂ and WO₃, a glass within the following composition range is preferred. Incidentally, the following composition is expressed in terms of mol %.

### 2. Resin

The resin supports the glass powder and the filler in the coated film after screen printing and is used as needed. Specific examples of the resin used here include ethyl cellulose, nitrocellulose, acrylic resin, vinyl acetate resin, butyral resin, melamine resin, alkyd resin and rosin resin. Of these, ethyl cellulose and nitrocellulose are used as a base resin. Incidentally, butyral resin, melamine resin, alkyd resin and rosin resin are used as an additive for enhancing the strength of the coated film. The debinderizing temperature at the firing is from 350 to 400° C. for ethyl cellulose and from 200 to 300° C. for nitrocellulose.

### 3. Solvent

The solvent dissolves the resin and adjusts the viscosity necessary for printing. Furthermore, the solvent does not dry during printing and rapidly dries in a drying process. A solvent having a boiling point of 200 to 230° C. is preferred. For adjusting the viscosity, solid content ratio and drying rate, solvents are blended. Specific examples of the solvent include, in view of driability of the paste at the screen printing, an ether-based solvent (e.g., butyl carbitol (BC), butyl carbitol acetate (BCA), diethylene glycol di-n-butyl ether, dipropylene glycol dibutyl ether, tripropylene glycol butyl ether, butyl cellosolve acetate), an alcohol-based solvent (e.g., α-terpineol, pine oil, Dowanol), an ester-based solvent (e.g., 2,2,4-trimethyl-1,3-pentanediol monoisobutyrate) and a phthalic acid ester-based solvent (e.g., DBP (dibutyl phthalate), DMP (dimethyl phthalate), DOP (dioctyl phthalate)). Of these, α-terpineol and 2,2,4-trimethyl-1,3-pentanediol monoisobutyrate are mainly used. Incidentally, DBP (dibutyl phthalate), DMP (dimethyl phthalate) and DOP (dioctyl phthalate) each functions also as a plasticizer.

### 4. Others

A surfactant may be used for adjusting the viscosity or promoting the frit dispersion. A silane coupling agent may be used for modifying the frit surface.

Production Method of Frit Paste Film

### (1) Frit Paste

A glass powder and a vehicle are prepared. The vehicle as used herein indicates a mixture of a resin, a solvent and a surfactant. More specifically, a resin, a surfactant and the like are charged into a solvent heated at 50 to 80° C., and the resulting mixture is allowed to stand for approximately from 4 to 12 hours and then filtered, whereby the vehicle is obtained.

Subsequently, the glass powder and the vehicle are mixed by a planetary mixer and then uniformly dispersed by a three-roll mill, and the resulting mixture is kneaded by a kneader so as to adjust the viscosity. Usually, the vehicle is used in a ratio of 20 to 30 wt % to 70 to 80 wt % of the glass material.

### (2) Printing

The frit paste produced in (1) is printed using a screen printer. The film thickness of the frit paste film formed can be controlled by the mesh roughness of screen plate, the thickness of emulsion, the pressing force during printing, the squeegee pressing amount or the like. After printing, the frit paste film is dried in a firing furnace.

### (3) Firing

The substrate after printing and drying is fired in the firing furnace. The firing comprises a debinderizing treatment of decomposing the resin in the frit paste to disappear and a firing treatment of sintering and softening the glass powder. The debinderizing temperature is from 350 to 400° C. for ethyl cellulose and from 200 to 300° C. for nitrocellulose, and the substrate is heated in an air atmosphere for 30 minutes to 1 hour. Thereafter, the temperature is raised, and the glass is sintered and softened. The firing temperature is from the softening temperature to the softening temperature +20° C., and the shape and size of a pore remaining in the inside vary depending on the treatment temperature. Furthermore, the substrate is cooled, whereby a glass layer is formed on the substrate. The thickness of the film obtained is from 5 to 30 μm, but a thicker glass layer can be formed by lamination during printing.

Incidentally, when a doctor blade printing method or a die coat printing method is used in the printing process above, a thicker film can be formed (green sheet printing). A green sheet is obtained by forming a film on a PET film or the like and then drying it. Subsequently, the green sheet is heat-pressed on the substrate by a roller or the like, and a fired film is obtained through the same firing procedure as that of the fit paste. The thickness of the film obtained is from 50 to 400 μm, but a thicker glass film can be formed by using a laminate of green sheets.

### Measuring Method of Refractive Index of Scattering Layer

The method for measuring the refractive index of the scattering layer includes the following two methods.

One is a method of analyzing the composition of the scattering layer, then preparing a glass having the same composition, and evaluating the refractive index by a prism method, and the other is a method of polishing the scattering layer to a small thickness of 1 to 2 μm, and performing an ellipsometry measurement in a pore-free region of about 10 μm in diameter to evaluate the refractive index. Incidentally, the present invention is based on the assumption that the refractive index is evaluated by a prism method.

Surface Roughness of Scattering Layer

The scattering layer has a main surface on which a translucent electrode is provided. As described above, the scattering layer of the present invention contains a scattering material. With respect to the diameter of the scattering material, as described above, as the diameter is larger, the light extraction efficiency can be more enhanced even when the content of the scattering material is small. However, according to experiments of the present inventors, there is a tendency that as the diameter is larger, when the scattering material is protruded from the main surface of the scattering layer, the arithmetic mean roughness (Ra) of the main surface of the scattering layer becomes larger. As described above, a translucent electrode is provided on the main surface of the scattering layer. Accordingly, the larger arithmetic average roughness (Ra) of the main surface of the scattering layer causes a problem that a short circuit between the translucent electrode and the scattering layer occurs and the organic LED element does not emit light. Patent Document 1, supra, discloses in paragraph 0010 that unevenness formed on the substrate poses a problem even when its size is on the order of several μm. According to experiments by the present inventors, it has been found that light emission of an organic LED element is not obtained when the unit is μm.

Translucent Electrode

The translucent electrode (anode) 103 is required to have a translucency of 80% or more so as to extract the light generated in the organic layer 110 to the outside. Furthermore, in order to inject many holes, a translucent electrode having a high work function is required. Specific examples of the material used therefor include ITO, SnO₂, ZnO, IZO (indium zinc oxide), AZO (ZnO—Al₂O₃: a zinc oxide doped with aluminum), GZO (ZnO—Ga₂O₃: a zinc oxide doped with gallium), Nb-doped TiO₂ and Ta-doped TiO₂. The thickness of the anode 103 is preferably 100 nm or more. Incidentally, the refractive index of the anode 103 is approximately from 1.9 to 2.2. Here, when the carrier concentration is increased, the refractive index of ITO can be decreased. ITO available on the market contains, as a standard, 10 wt % of SnO₂. The refractive index of ITO can be decreased by increasing the Sn concentration more than the standard value. The increase in the Sn concentration leads to an increase in the carrier concentration, but the mobility and transmittance are decreased. The amount of Sn needs to be determined by the balance of these properties.

Incidentally, the translucent electrode can be of course used as the cathode.

Organic Layer (Layer Having Light-Emitting Function)

The organic layer 110 is a layer having a light-emitting function and is composed of a hole injection layer, a hole transport layer, a light-emitting layer, an electron transport layer and an electron injection layer. The refractive index of the organic layer 110 is approximately from 1.7 to 1.8.

Hole Injection Layer

In order to reduce the barrier for hole injection from the translucent electrode 103 as the anode, a hole injection layer having a small difference in the ionization potential is required. Enhancement of the charge injection efficiency from the electrode interface in the hole injection layer brings a decreased driving voltage of the element as well as an increased charge injection efficiency. The material widely used for the hole injection layer is, in the case of a polymer material, polystyrene sulfonic acid (PSS)-doped polyethylenedioxythiophene (PEDOT:PSS) and in the case of a low-molecular material, a phthalocyanine-based material, that is, copper phthalocyanine (CuPc).

Hole Transport Layer

The hole transport layer plays a role of transporting a hole injected from the hole injection layer to the light-emitting layer and is required to have appropriate ionization potential and hole mobility. Specific examples of the material used therefor include a triphenylamine derivative, N,N′-bis(1-naphthyl)-N,N′-diphenyl-1,1′-biphenyl-4,4′-diamine (NPD), N,N′-diphenyl-N,N′-bis[N-phenyl-N-(2-naphthyl)-4′-aminobiphenyl-4-yl]-1,1′-biphenyl-4,4′-diamine (NPTE), 1,1-bis[(di-4-tolylamino)phenyl]cyclohexane (HTM2) and N,N′-diphenyl-N,N′-bis(3-methylphenyl)-1,1′-diphenyl-4,4′-diamine (TPD). The thickness of the hole transport layer is preferably from 10 to 150 nm. As the thickness is smaller, the voltage can be lower, but in view of the problem of inter-electrode short circuit, it is particularly preferred that the thickness is from 10 to 150 nm.

Light-Emitting Layer

As for the light-emitting layer, a material providing a field for recombination of the injected electrons and holes and at the same time, having high luminous efficiency is used. To describe this in detail, a light-emitting host material and a light-emitting dye as a doping material, which are used in the light-emitting layer, function as recombination centers for the holes and electrons injected from the anode and cathode. Also, doping of a light-emitting dye into the host material in the light-emitting layer provides high luminous efficiency and at the same time, converts the emission wavelength. These materials are required, for example, to have an energy level suitable for charge injection, be excellent in chemical stability and heat resistance and form a homogeneous amorphous thin film. Also, the materials are required to be excellent in the kind of emission color and the color purity and have high luminous efficiency. The light-emitting material that is an organic material includes a low-molecular material and a polymer material. Furthermore, the light-emitting materials are classified into a fluorescent material and a phosphorescent material according to the light-emitting mechanism. Specific examples of the material for the light-emitting layer include a metal complex of a quinoline derivative, such as tris(8-quinolinolate)aluminum complex (Alq₃), bis(8-hydroxy)quinaldine aluminum phenoxide (Alq′₂OPh), bis(8-hydroxy)quinaldine aluminum 2,5-dimethylphenoxide (BAlq), mono(2,2,6,6-tetra-methyl-3,5-heptanedionate)lithium complex (Liq), mono(8-quinolinolate)sodium complex (Naq), mono(2,2,6,6-tetramethyl-3,5-heptanedionate)lithium complex, mono(2,2,6,6-tetramethyl-3,5-heptanedionate)sodium complex and bis(8-quinolinolate)calcium complex (Caq₂); and a fluorescent substance such as tetraphenylbutadiene, phenylquinacridone (QD), anthracene, perylene and coronene. The host material is preferably a quinolinolate complex, more preferably an aluminum complex having 8-quinolinol or a derivative thereof as a ligand.

Electron Transport Layer

The electron transport layer plays a role of transporting a hole injected from the electrode. Specific examples of the material used for the electron transport layer include a quinolinol aluminum complex (Alq₃), an oxadiazole derivative (e.g., 2,5-bis(1-naphthyl)-1,3,4-oxadiazole (BND), 2-(4-tert-butylphenyl)-5-(4-biphenyl)-1,3,4-oxadiazole (PBD)), a triazole derivative, a bathophenanthroline derivative and a silole derivative.

Electron Injection Layer

As for the electron injection layer, a layer capable of enhancing the electron injection efficiency is required. Specifically, the electron injection layer is formed by providing a layer doped with an alkali metal such as lithium (Li) or cesium (Cs) on the cathode interface.

Translucent Electrode

The reflective electrode (cathode) 120 is formed using a translucent film such as ITO, similarly to the anode, and is sometime formed through an ultrathin film of a metal having a small work function or an alloy thereof. Specific examples of the metal include an alkali metal, an alkaline earth metal, and a metal of Group 3 in the Periodic Table. Of these, aluminum (Al), magnesium (Mg), an alloy thereof and the like are preferred, because these are an inexpensive material having good chemical stability. In any case, the electrode is a laminate film of an ultrathin film and a translucent electrically conductive film.

Production Method of Electrode-Attached Substrate (Organic LED Element)

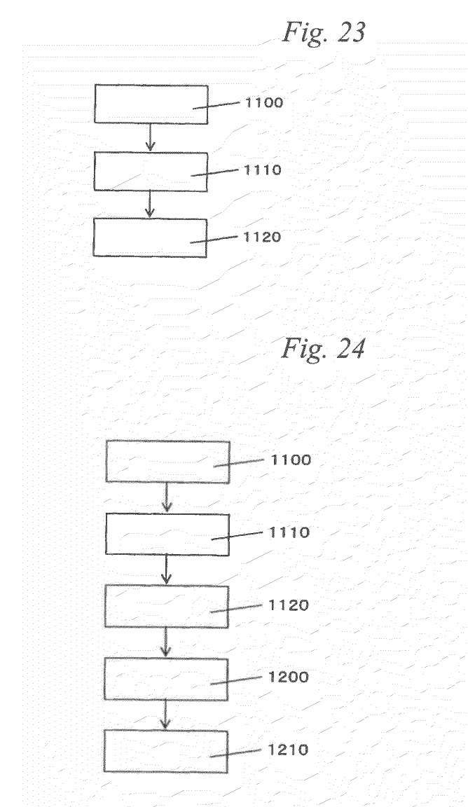

The production method of an electrode-attached translucent substrate of the invention is described below by referring to the drawing. FIG. 23 is a flow chart showing the production method of an electrode-attached substrate of the present invention. The production method of an electrode-attached substrate of the present invention comprises a step of preparing a reflective substrate (step 1100), a step of forming on the reflective substrate a scattering layer comprising a base material having a first refractive index at a wavelength of emitted light of the organic LED element and a plurality of scattering materials being provided inside of the base material and differing in the refractive index from the base material (step 1110), and a step of forming a translucent electrode on the scattering layer (step 1120).

First, a reflective substrate in which a translucent substrate is coated with a reflective film is prepared (step 1100). The translucent substrate used here is specifically a glass substrate or a plastic substrate.

Subsequently, a scattering layer comprising a base material having a first refractive index at a wavelength of emitted light of the organic LED element and a plurality of scattering materials being provided inside of the base material and differing in the refractive index from the base material is prepared, and the scattering layer prepared is formed on the reflective substrate (step 1110).

Thereafter, a translucent electrode, preferably a translucent electrode having a second refractive index equal to or lower than the first refractive index, is formed on the scattering layer (step 1120). To describe specifically, the translucent electrode is formed by film-forming ITO on the substrate and etching the ITO film. The ITO film can be uniformly formed on the entire surface of the reflective film-coated glass substrate by sputtering or vapor deposition. An ITO pattern is formed by photolithography and etching. This ITO pattern becomes the translucent electrode (anode). A phenol novolak resin is used as a resist, and exposure and development are performed. The etching may be either wet etching or dry etching. For example, ITO can be patterned using a mixed aqueous solution of hydrochloric acid and nitric acid. The resist remover which can be used is, for example, monoethanolamine.

Production Method of Organic LED Element

The production method of an organic LED element of the present invention is described below by referring to the drawing. FIG. 24 is a flow chart showing the production method of an organic LED element of the invention. The production method of an organic LED element of the present invention comprises a step of preparing a reflective substrate (step 1100), a step of forming on the reflective substrate a scattering layer comprising a base material having a first refractive index at a wavelength of emitted light of the organic LED element and a plurality of scattering materials being provided inside of the base material and differing in the refractive index from the base material (step 1110), a step of forming a translucent electrode on the scattering layer (step 1120), a step of forming an organic layer on the translucent electrode (step 1200) and a step of forming a translucent electrode on the organic layer (step 1210).

After performing the above-described steps 1100 to 1120, an organic layer is formed on the translucent electrode (step 1200). The organic layer is formed here by using a coating method and a vapor deposition method in combination. For example, when some one or more layers of the organic layer are formed by a coating method, other layers are formed by a vapor deposition method. In the case of forming a layer by a coating method and thereafter forming a layer thereon by a vapor deposition method, condensation, drying and curing are performed before forming an organic layer by a vapor deposition method. Also, the organic layer may be formed only by a coating method or only by a vapor deposition method.

Thereafter, a translucent electrode is formed on the organic layer (step 1210). To describe specifically, the translucent electrode is formed by vapor-depositing a translucent material such as ITO on the organic layer.

A step of producing an opposed substrate for sealing so as to seal the organic LED element formed through the above-described steps is described below. First, a glass substrate different from the element substrate is prepared. This glass substrate is processed to form a desiccant-housing part for housing a desiccant. As for the desiccant-housing part, the glass substrate is coated with a resist, a part of the substrate is exposed by exposure and development, and the exposed portion is made thin by etching, thereby forming the desiccant-housing part.

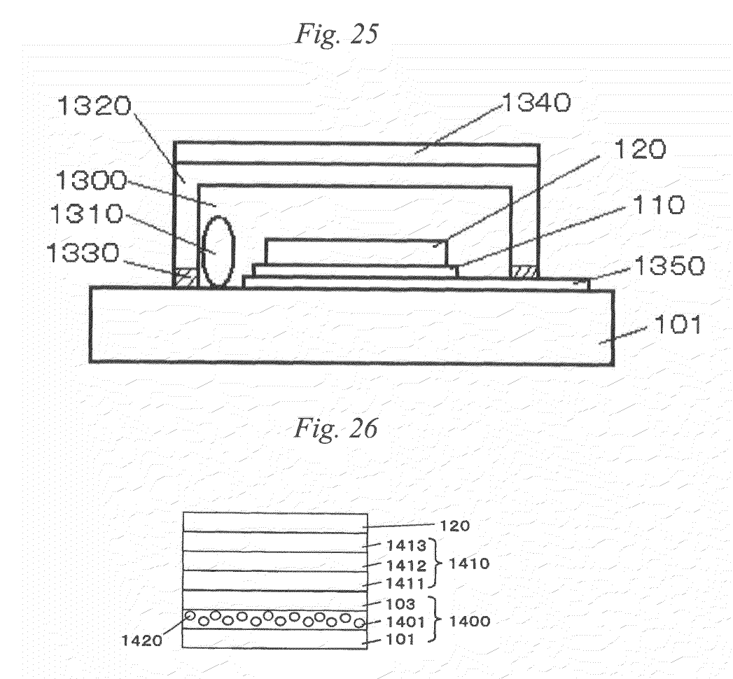

As shown in FIG. 25, a desiccant 1310 such as calcium oxide is disposed in the desiccant-housing part 1300 provided in the periphery of the organic layer 110 as the light-emitting layer, and thereafter, two substrates are laminated together and bonded. FIG. 25 is a cross-sectional view schematically showing a construction of an organic LED display device. Specifically, a seal material 1330 is coated using a dispenser on the opposed substrate 1320 surface where the desiccant-housing part 1300 is provided. Examples of the seal material 1330 which can be used include an epoxy-based UV-curable resin. The seal material 1330 is also coated on the entire outer circumference of the region facing the organic LED element. These two substrates are faced each other by aligning the positions and then irradiated with UV light to cure the seal material, thereby bonding the substrates to each other. Thereafter, in order to more accelerate the curing of the seal material, for example, a heat treatment is applied in a clean oven at 80° C. for 1 hour. As a result, a space between the substrates, in which the organic LED element is present, is isolated from the outside of the substrates by the seal material and the paired substrates. By virtue of disposing a desiccant 1310, the organic LED element can be prevented from deterioration due to water or the like remaining in or intruding into the sealed space.

Light emission from the organic layer 110 is caused to exit upward in the Figure. An optical sheet 1340 is attached to the opposed substrate 1320 opposite the surface where the organic LED element is formed, that is, to the light exit surface. The optical sheet 1340 has a polarizing plate and a ¼ wavelength plate and functions as an antireflective film. The light from the organic thin film layer is extracted on the side of the surface where this optical sheet 1340 is provided.

Unnecessary portions in the vicinity of the outer periphery of the substrates are cut and removed. A signal electrode driver is connected to anode wiring 1350, and a scanning electrode driver is connected to cathode connection wiring. At an end part of the substrate, a terminal part connected to each wiring is formed. An anisotropically conductive film (ACF) is attached to this terminal part, and a TCP (tape carrier package) having provided therein a driving circuit is connected thereto. Specifically, the ACF is temporarily press-bonded to the terminal part, and the TCP containing the driving circuit is then securely press-bonded thereto, whereby the driving circuit is mounted. This organic LED display panel is attached to a casing to complete the organic LED display device. The element described above is a dot matrix display element, but the display may be a character display. Also, the element is not limited to the above-described construction depending on the element specification.

### Embodiment 4

### Another Construction Example of Organic LED Element

The organic LED element according to embodiment 4 of the present invention is described below by referring to the drawing. Incidentally, the same reference numerals as in FIG. 1 are given to the same constituents, and descriptions thereof are omitted. FIG. 26 is a cross-sectional view showing a laminate for the organic LED element of the present invention and another structure of the laminate for the organic LED element. The another organic LED element of the present invention comprises a translucent electrode-attached reflective substrate (laminate for an organic LED element) 1400, an organic layer 1410 and a translucent electrode 120. The translucent electrode-attached substrate 1400 is composed of a reflective substrate 101, a scattering layer 1401 and a translucent electrode 103. The organic layer 1410 is composed of a hole injection-transport layer 1411, a light-emitting layer 1412 and an electron injection-transport layer 1413.

Here, the light-emitting layer of the organic LED element according to embodiment 1 shown in FIG. 1 is composed of three layers, and any one of three layers is formed to emit light in any one color of three light emission colors (red, green and blue). However, in the organic LED element of FIG. 26, a plurality of scattering materials 1420 provided inside of the scattering layer 1401 are allowed to act as a fluorescent emission material (for example, a filler) capable of emitting red light and green light, so that the light-emitting layer 1412 can be composed of one layer emitting only blue light. In other words, according to another construction of the organic LED element of the present invention, the light-emitting layer can be a layer emitting light in any one color of blue, green and red, and this produces an effect that the organic LED element can be downsized.

The translucent electrode-attached substrate of the present invention is not limited in its application only to an organic LED element but is also effective to increase the efficiency of optical devices such as various light-emitting devices (e.g., inorganic EL element, liquid crystal) and light-receiving devices (e.g., light quantity sensor, solar cell).

### EXAMPLES

### Example 1

### Experimental Proof of Effect of Scattering Layer

An experimental proof for showing that the scattering layer is effective in enhancing the light extraction efficiency is described below. Sample 1 is Example having the scattering layer of the present invention, and Sample 2 is Comparative Example having a scattering layer where a scattering material is not provided in the inside. The calculation method is the same as the calculation method of the scattering layer described above. The conditions and results (extraction efficiency) of each sample are shown in Table 2 below.

TABLE 2

| | Sample 1 | Sample 2 |
|---|---|---|
| Electron injection-transport layer | | |
| Thickness (μm) | 1 | 1 |
| Refractive Index | 1.9 | 1.9 |
| Light-emitting Layer | | |
| Thickness (μm) | 1 | 1 |
| Refractive index | 1.9 | 1.9 |
| Hole injection-transport layer | | |
| Thickness (μm) | 1 | 1 |
| Refractive index | 1.9 | 1.9 |
| Scattering layer | | |
| Base material | | |
| Thickness (μm) | 30 | 30 |
| Refractive index | 1.9 | 1.9 |
| Transmittance (%) | 100 | 100 |
| Scattering material | | |
| Diameter (μm) | 5 | — |
| Refractive index | 1 | — |
| Number of particles (@ 1 mm²) | 1527932.516 | — |
| Content (vol %) | 10 | — |
| Transmittance (%) | 100 | — |
| Glass substrate | | — |
| Thickness (μm) | 100 | — |
| Refractive index | 1.54 | — |
| Light flux | | |
| Number of light rays extracted | 811.1/1000 | 210.4/1000 |
| from front face | | |
| Number of light rays extracted | 47.86/1000 | 125/1000 |
| from side face | | |
| Front extraction efficiency (%) | 81.11 | 21.04 |

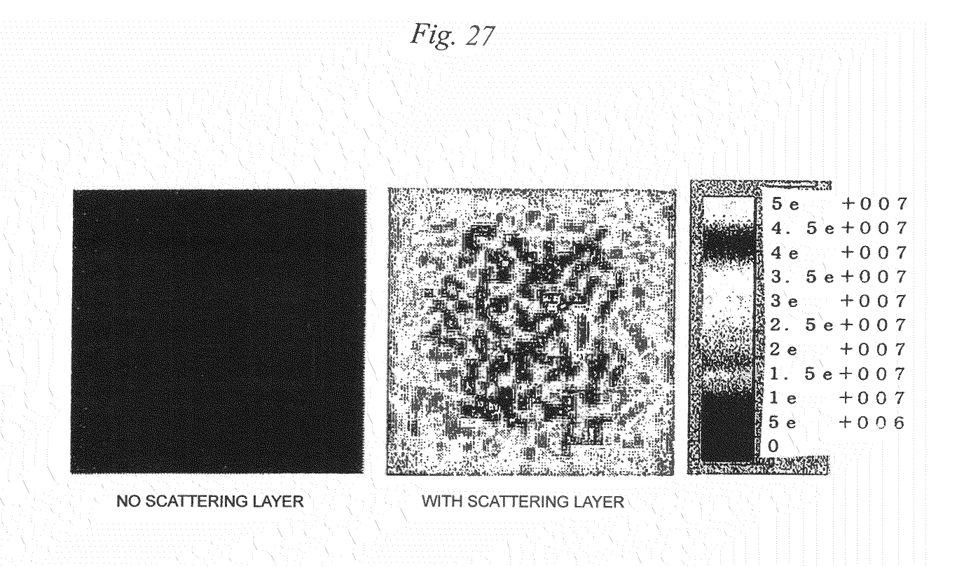

FIG. 27 shows the comparison results of front extraction efficiency between Example and Comparative Example. FIGS. 27(a) and 27(b) are views showing the results when observed from the light extraction surface side under conditions of Samples 1 and 2, respectively. As shown in FIG. 27, according to the electrode-attached substrate and organic LED element of the present invention, the light extraction efficiency that is about 20% when untreated can be enhanced to about 80%.

The contents and results of evaluation tests performed for confirming that the electrode-attached substrate of the present invention improves the outside extraction efficiency are described below by referring to the drawings.

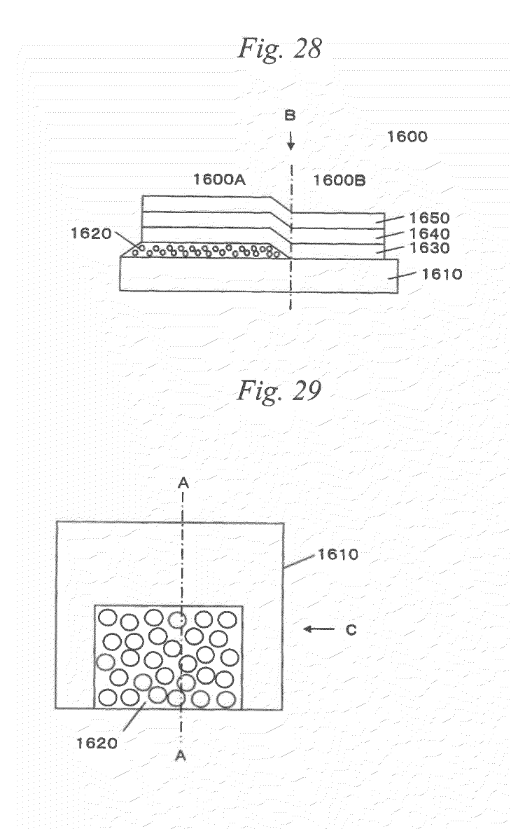

First, an evaluation element shown in FIG. 28 and FIG. 29 was prepared. Here, FIG. 28 is a cross-sectional view taken along line A-A as seen from the direction C in FIG. 29, showing the structure of the evaluation element. FIG. 29 is a top view of the evaluation element as seen from the direction B in FIG. 28. Incidentally, in FIG. 29, for the purpose of clarifying the positional relationship between a glass substrate 1610 and a scattering layer 1620, only a glass substrate 1610 and a scattering layer 1620 are illustrated. The glass substrate is used as a reflective substrate by forming a reflective film such as silver film on the back side.

The evaluation element has a glass substrate 1610, a scattering layer 1620, an ITO film 1630, an Alq₃ (tris(8-quinolinolate)aluminum complex) film 1640 and an ITO film 1650. Here, in order to compare the difference in light extraction efficiency by the presence or absence of a scattering layer, the evaluation element was divided into two parts, that is, a region 1600A having a scattering layer and a region 1600B having no scattering layer. In the evaluation element of the region 1600A having a scattering layer, a scattering layer 1620 is formed on the glass substrate 1610, and in the evaluation element of the region 1600B having no scattering layer, an ITO film 1630 is formed on the glass substrate 1610.

As for the glass substrate, a glass substrate [PD200 (trade name), manufactured by Asahi Glass Co., Ltd.] was used. This glass has a strain point of 570° C. and a thermal expansion coefficient of 83×10⁻⁷ (1/° C.). The glass substrate having such a high strain point and a high thermal expansion coefficient is suitable when forming the scattering layer by firing a glass fit paste.

The scattering layer 1620 is a high refractive index glass frit paste layer. Here, a glass having the composition shown in Table 3 was prepared as the scattering layer 1620. This glass has a glass transition temperature of 483° C., a deformation point of 528° C. and a thermal expansion coefficient of 83×10⁻⁷ (1/° C.). The refractive index nF of this glass at the F line (486.13 nm) is 2.03558, the refractive index nd at the d line (587.56 nm) is 1.99810, and the refractive index nC at the C line (656.27 nm) is 1.98344. The refractive index was measured by a refractometer (manufactured by Kalnew Optical Industrial Co., Ltd., trade name: KRP-2). The glass transition temperature (Tg) and deformation point (At) were measured with a thermal analysis instrument (manufactured by Bruker, trade name: TD5000SA) by a thermal expansion method at a temperature rise rate of 5° C./min.

TABLE 3

| | Mass % | Mol % |
|---|---|---|
| P₂O₅ | 16.4 | 23.1 |
| B₂O₃ | 1.9 | 5.5 |
| Li₂O | 1.7 | 11.6 |
| Na₂O | 1.2 | 4.0 |
| K₂O | 1.2 | 2.5 |
| Bi₂O₃ | 38.6 | 16.6 |
| TiO₂ | 3.5 | 8.7 |
| Nb₂O₅ | 23.3 | 17.6 |
| WO₃ | 12.1 | 10.4 |

A scattering layer 1620 was formed by the following procedure. A powder raw material was prepared to have a composition indicated by the ratio of Table 3. The powder raw material prepared was dry milled in an alumina-made ball mill for 12 hours to produce a glass powder having an average particle diameter (d50, particle size at an integrated value of 50%, unit: μm) of 1 to 3 μm. Subsequently, 75 g of the obtained glass powder was kneaded with 25 g of an organic vehicle (prepared by dissolving about 10 mass % of ethyl cellulose in α-terpineol or the like) to produce a paste ink (glass paste). This glass paste was uniformly printed on the above-described glass substrate to a film thickness after firing of 15 μm, 30 μm, 60 μm or 120 μm. After drying at 150° C. for 30 minutes, the temperature was once returned to room temperature, then raised to 450° C. over 45 minutes, held at 450° C. for 10 hours, again raised to 550° C. over 12 minutes, held at 550° C. for 30 minutes, and thereafter, lowered to room temperature over 3 hours, whereby a glass layer was formed on the glass substrate. The surface of the scattering layer having a film thickness of 120 μm was polished to a film thickness of 60 μm. In the thus-formed glass film, many pores were contained, and scattering was caused to occur by these pores. Whereas, on the outermost glass surface of the scattering layer, waviness was observed, but local unevenness giving rise to an inter-electrode short circuit of an organic LED element, such as opened pore, was not observed.

### Example 2

### Experimental Proof of Flatness of Main Surface of Scattering Layer

An experimental proof for showing that a flat main surface (the arithmetic mean roughness is 30 nm or less) of the scattering layer is effective in enhancing the light extraction efficiency is described below.

As for the glass substrate, the above-described glass substrate PD200 manufactured by Asahi Glass Co., Ltd. was used. The scattering layer was produced as follows. A powder raw material was prepared to have the glass composition shown in Table 3, melted in an electric furnace at 1,100° C., and cast into a roll to obtain glass flakes. This glass has a glass transition temperature of 499° C., a deformation point of 545° C. and a thermal expansion coefficient of 74×10⁻⁷ (1/° C.) (an average value in the range of 100 to 300° C.). The refractive index nF of this glass at the F line (486.13 nm) is 2.0448, the refractive index nd at the d line (587.56 nm) is 2.0065, and the refractive index nC at the C line (656.27 nm) is 1.9918. The methods for measuring the refractive index and the glass transition point/deformation point are the same as in Example above. When the glass substrate is used as a reflective substrate, this is used by forming an aluminum thin film (reflective film) on the back side.

The flakes produced were further pulverized in a zirconia-made planetary mill for 2 hours and sieved to produce a powder. As for the particle size distribution at this time, D₅₀ was 0.905 μm, D₁₀ was 0.398 μm, and D₉₀ was 3.024 μm. Subsequently, 20 g of the obtained glass powder was kneaded with 7.6 g of an organic vehicle to produce a glass paste. This glass paste was uniformly printed on the above-described glass substrate to a circular form having a diameter of 10 mm and a film thickness after firing of 15 μm. After drying at 150° C. for 30 minutes, the temperature was once returned to room temperature, then raised to 450° C. over 45 minutes, held for firing at 450° C. for 30 minutes, again raised to 550° C. over 12 minutes, held at 550° C. for 30 minutes, and thereafter, lowered to room temperature over 3 hours, whereby a scattering layer was formed on the glass substrate. Other scattering layers were also prepared using the same temperature profile except that only the temperature held for firing was changed to 570° C. or 580° C.

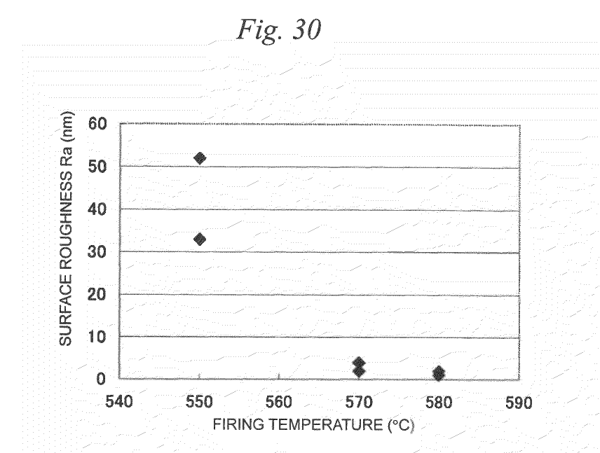

The surface roughness of these samples was measured. In the measurement, a three-dimensional non-contact surface profile measuring system, Micromap, manufactured by Ryoka Systems Inc. was used. The surface roughness was measured at two points in the vicinity of the central part of the circular scattering layer, and the measuring region was a square with sides each 30 μm long. The cutoff wavelength of waviness was set to 10 μm. It is considered that when the period of unevenness is 10 μm or more, the film for use in the formation of an organic LED element, which is formed by a method such as sputtering, vapor deposition, spin coating or spraying, can sufficiently follow the unevenness. If the period of unevenness is less than 10 μm, the unevenness is considered to sometimes fail in ensuring sufficient coatability by vapor deposition or the like. FIG. 30 shows the arithmetic mean roughness (Ra) of the scattering layer fired at each temperature. In the scattering layer fired at 550° C., because of insufficient firing, the pore in the scattering layer is not spherical or the surface is roughened and when an element is produced thereon, a trouble such as inter-electrode short circuit is liable to occur. On the other hand, in the layers fired at 570° C. and 580° C., the pore in the scattering layer is spherical and the surface is smooth.

The thus-produced scattering layer-attached glass substrate had a total light transmittance of 77.8 and a haze value of 85.2. The measurement was performed using a haze computer (trade name: HZ-2) manufactured by Suga Test Instruments Co., Ltd. as a measurement device and using an untreated plate of the glass substrate [PD200] as a reference.

Incidentally, the pore and the crystal are generated by different mechanisms and therefore, only a pore or only a crystal can be generated by controlling the glass material, powder particle diameter, surface state, firing conditions (atmosphere, pressure) or the like. For example, crystal precipitation is inhibited by increasing a network former in the glass or increasing an alkali oxide component for suppressing crystal precipitation, and pore generation is inhibited by performing the firing under reduced pressure.

A scattering material is present in the glass scattering layer and therefore, the surface of the reflective substrate produced by forming a reflective film on the back side of a glass substrate is not visually recognized as a mirror surface, but if the scattering property is decreased, the surface may be visually recognized as a mirror surface to give a disadvantageous effect in view of appearance.

While the invention has been described in detail and with reference to specific embodiments thereof, it will be apparent to one skilled in the art that various changes and modifications can be made therein without departing from the spirit and scope of the invention.

This application is based on Japanese Patent Application No. 2009-014795 filed on Jan. 26, 2009, the entirety of which is incorporated herein by way of reference.

As described in the foregoing pages, the electrode-attached substrate of the present invention comprises a stable scattering layer with excellent light scattering property and high reliability and thanks to its capability of increasing light extraction or incorporation efficiency, the electrode-attached substrate of the present invention is applicable to a light-emitting device, a light-receiving device and the like.

What is claimed is:

1. An electrode-attached substrate comprising:
a reflective substrate,
a scattering layer formed on said substrate and composed of a glass layer comprising a plurality of scattering materials, and
a translucent electrode formed on said scattering layer.

2. The electrode-attached substrate according to claim 1, wherein the scattering layer is composed of a glass comprising a base material having a first refractive index for at least one wavelength of light to be transmitted and a plurality of scattering materials being dispersed in the base material and having a second refractive index different from the refractive index of the base material,
and wherein a distribution of the scattering materials in the scattering layer decreases from an inside of the scattering layer toward the translucent electrode.

3. The electrode-attached substrate according to claim 1, wherein the translucent electrode has a third refractive index equal to or lower than the first refractive index.

4. The electrode-attached substrate according to claim 1, wherein a density ρ₃ of the scattering materials at a distance x (x≦0.2 μm) from a surface of the scattering layer on a translucent electrode side and a density ρ₄ of the scattering materials at a distance x of 2 μm satisfy ρ₄>ρ₃.

5. The electrode-attached substrate according to claim 1, wherein a surface roughness Ra of the surface of the scattering layer is 30 nm or less.

6. The electrode-attached substrate according to claim 1, wherein a content of the scattering materials in the scattering layer is at least 1 vol %.

7. The electrode-attached substrate according to claim 1, wherein the scattering materials are pores.

8. The electrode-attached substrate according to claim 2, wherein the scattering materials are material particles having a composition different from that of the base material.

9. The electrode-attached substrate according to claim 2, wherein the scattering materials are precipitated crystals of the glass constituting the base material.

10. The electrode-attached substrate according to claim 1, wherein the number of the scattering materials per 1 mm² of the scattering layer is at least 1×10⁴.

11. The electrode-attached substrate according to claim 1, wherein, in the scattering materials, the ratio of scattering materials having a maximum length of 5 μm or more is 15 vol % or less.

12. The electrode-attached substrate according to claim 1, wherein the scattering layer is selectively formed to constitute a desired pattern on the reflective substrate.

13. The electrode-attached substrate according to claim 2, wherein the first refractive index for at least one wavelength of wavelengths λ (430 nm<λ<650 nm) is 1.8 or more.

14. The electrode-attached substrate according to claim 1, wherein the scattering layer has an average thermal expansion coefficient over the range of 100° C. to 400° C. of 70×10⁻⁷(° C.⁻¹) to 95×10⁻⁷(° C.⁻¹), and a glass transition temperature of 450° C. to 550° C.

15. The electrode-attached substrate according to claim 2, wherein the base material of the scattering layer is a glass containing, in terms of mol %, from 15 to 30% of P₂O₅, from 0 to 15% of SiO₂, from 0 to 18% of B₂O₃, from 5 to 40% of Nb₂O₅, from 0 to 15% of TiO₂, from 0 to 50% of WO₃, from 0 to 30% of Bi₂O₃, provided that Nb₂O₅+TiO₂+WO₃+Bi₂O₃ is from 20 to 60%, from 0 to 20% of Li₂O, from 0 to 20% of Na₂O, from 0 to 20% of K₂O, provided that Li₂O+Na₂O+K₂O is from 5 to 40%, from 0 to 10% of MgO, from 0 to 10% of CaO, from 0 to 10% of SrO, from 0 to 20% of BaO, from 0 to 20% of ZnO and from 0 to 10% of Ta₂O₅.

16. A method for producing an electrode-attached substrate, said method comprising steps of:
preparing a reflective substrate;
forming on said substrate a scattering layer composed of a glass layer comprising a plurality of scattering materials; and
forming a translucent electrode on the scattering layer.

17. The method for producing an electrode-attached substrate according to claim 16, wherein the step of forming a scattering layer includes steps of:
coating a glass powder-containing coating material on said substrate; and
firing said coated glass powder,
the scattering layer formed comprises a base material having a first refractive index and a plurality of scattering materials being dispersed in the base material and having a second refractive index different from the refractive index of the base material, and
an intralayer distribution of the scattering materials in the scattering layer decreases from an inside of the scattering layer toward an outermost surface thereof.

18. An organic LED element comprising:
the electrode-attached substrate according to claim 1,
an organic layer formed on the translucent electrode, and
an another translucent electrode formed on the organic layer.

19. The organic LED element according to claim 18, wherein the scattering layer comprises a base material having a first refractive index for at least one wavelength of wavelengths of emitted light of the organic LED element and a plurality of scattering materials being positioned inside of the base material and having a second refractive index different from the refractive index of the base material, and a distribution of the scattering materials in the scattering layer decreases from an inside of the scattering layer toward the translucent electrode.

20. A method for producing an organic LED element, said method comprising steps of:
preparing a reflective substrate,
forming on said substrate a scattering layer composed of a glass comprising a base material having a first refractive index for at least one wavelength of wavelengths of emitted light of the organic LED element and a plurality of scattering materials being positioned inside of the base material and having a second refractive index different from the refractive index of the base material,
forming a first translucent electrode on the scattering layer,
forming an organic layer on the first translucent electrode, and
forming a second translucent electrode on the organic layer.
